(19) United States
(12) Patent Application Publication
(10) Pub. No.: US 2026/0114098 A1
(43) Pub. Date: Apr. 23, 2026

(54) DISPLAY DEVICE AND ELECTRONIC DEVICE INCLUDING THE SAME

(71) Applicant: Samsung Display Co., Ltd., Yongin-si (KR)

(72) Inventors: JONGWON LEE, Yongin-si (KR); JAEWOONG KANG, Yongin-si (KR); JINHYUK JANG, Yongin-si (KR); Yongwoo RYU, Yongin-si (KR); KOOKHYUN HAN, Yongin-si (KR)

(73) Assignee: Samsung Display Co., Ltd., Yongin-si (KR)

(21) Appl. No.: 19/256,606

(22) Filed: Jul. 1, 2025

(30) Foreign Application Priority Data
Oct. 21, 2024 (KR) 10-2024-0144033

(51) Int. Cl. H10H 29/41; H01L 25/16; H10H 29/49

(52) U.S. Cl. CPC H10H 29/41; H10H 29/49; H10W 90/00

(57) ABSTRACT

Provided is a display device including a complementary metal oxide semiconductor (CMOS) wafer and an emission structure layer disposed on the CMOS wafer. The emission structure layer includes first light emitting diodes which emit light having a first wavelength, second light emitting diodes which emit light having a second wavelength different from the first wavelength, and third light emitting diodes which emit light having a third wavelength different from the first wavelength and the second wavelength. Each first light emitting diode includes a first emission structure and a first insulating layer, each second light emitting diode includes a second emission structure and a second insulating layer, and each third light emitting diode includes a third emission structure and a third insulating layer. At least one of the first insulating layer, the second insulating layer, or the third insulating layer includes a different material from the remaining insulating layers.

### CROSS-REFERENCE TO RELATED APPLICATION(S)

This application claims priority to and benefits of Korean Patent Application No. 10-2024-0144033 under 35 U.S.C. § 119, filed Oct. 21, 2024, in the Korean Intellectual Property Office, the entire contents of which are incorporated herein by reference.

### BACKGROUND

### 1. Technical Field

The disclosure herein relates to a display device and an electronic device including the display device, and more particularly, to a display device and an electronic device including a complementary metal oxide semiconductor (CMOS) wafer and a light emitting diode.

### 2. Description of the Related Art

Electronic devices such as smartphones, notebook computers, navigation devices and smart televisions, which provide images for users, include display devices for displaying the images. Augmented reality devices, virtual reality devices, and video projection devices may include micro display devices. The micro display devices may include complementary metal oxide semiconductor (CMOS) wafers and light emitting diodes disposed on the CMOS wafers in order to be driven at low powers and also display images with high luminance.

### SUMMARY

The disclosure provides a display device and an electronic device with improved display efficiency.

A display device according to an embodiment of the disclosure may include a complementary metal oxide semiconductor (CMOS) wafer and an emission structure layer disposed on the CMOS wafer. The emission structure layer includes a plurality of first light emitting diodes which are disposed on the CMOS wafer and emit light having a first wavelength, a plurality of second light emitting diodes which are disposed on the CMOS wafer and emit light having a second wavelength different from the first wavelength, and a plurality of third light emitting diodes disposed on the CMOS wafer and emit light having a third wavelength different from the first wavelength and the second wavelength. Each of the plurality of first light emitting diodes includes a first emission structure and a first insulating layer which covers a side surface of the first emission structure, each of the plurality of second light emitting diodes includes a second emission structure and a second insulating layer which covers a side surface of the second emission structure, and each of the plurality of third light emitting diodes includes a third emission structure and a third insulating layer which covers a side surface of the third emission structure. At least one of the first insulating layer, the second insulating layer, or the third insulating layer includes a different material from the remaining insulating layers.

The first insulating layer may include a different material from the second insulating layer, and the second insulating layer and the third insulating layer may include a same material.

The first insulating layer, the second insulating layer, and the third insulating layer may include different materials.

The first insulating layer may be in contact with the side surface of the first emission structure, the second insulating layer may be in contact with the side surface of the second emission structure, and the third insulating layer may be in contact with the side surface of the third emission structure.

Each of the plurality of first light emitting diodes may further include a first additional insulating layer spaced apart from the first emission structure with the first insulating layer disposed between each first light emitting diode and the first additional insulating layer, each of the plurality of second light emitting diodes may further include a second additional insulating layer spaced apart from the second emission structure with the second insulating layer disposed between each second light emitting diode and the first additional insulating layer, and each of the plurality of third light emitting diodes may further include a third additional insulating layer spaced apart from the third emission structure with the third insulating layer disposed between each third light emitting diode and the third additional insulating layer.

At least a portion of each of the plurality of first light emitting diodes may not overlap the plurality of second light emitting diodes and the plurality of third light emitting diodes in a plan view.

A first insulating material included in the first insulating layer may include a high-k dielectric material compared to a second insulating material included in the second insulating layer.

The first insulating material may include at least one of hafnium oxide, lanthanum oxide, zirconium oxide, tantalum oxide, hafnium oxynitride, zirconium oxynitride, tantalum oxynitride, hafnium nitride, lanthanum nitride, or zirconium nitride.

The second insulating material may include at least one of silicon oxide or aluminum oxide.

The first wavelength may be shorter than shorter than each of and the second wavelength and the third wavelength.

Each of the plurality of first light emitting diodes may further include a first lower conductive pattern disposed below the first emission structure, and a first upper conductive pattern disposed above the first emission structure, each of the plurality of second light emitting diodes may further include a second lower conductive pattern disposed below the second emission structure, and a second upper conductive pattern disposed above the second emission structure, and each of the plurality of third light emitting diodes may further include a third lower conductive pattern disposed below the third emission structure, and a third upper conductive pattern disposed above the third emission structure.

The display device may further include a plurality of lenses disposed on the emission structure layer and overlapping at least some of the plurality of first light emitting diodes, the plurality of second light emitting diodes, and the plurality of third light emitting diodes.

The CMOS wafer may include a first area in which the plurality of first light emitting diodes, the plurality of second light emitting diodes, and the plurality of third light emitting diodes are respectively disposed, and a second area provided outside the first area in a plan view.

The emission structure layer may further include a common electrode electrically connected to at least a portion of the plurality of first light emitting diodes, the plurality of second light emitting diodes, and the plurality of third light emitting diodes.

The emission structure layer may further include a planarization layer disposed between at least some of the plurality of first light emitting diodes, the plurality of second light emitting diodes, and the plurality of third light emitting diodes.

An electronic device according to an embodiment of the disclosure may include: a display module; and a processor including at least one of a central processing unit, an application processor, a graphic processing unit, a communication processor, an image signal processor, and a controller, wherein a display device may include a complementary metal oxide semiconductor (CMOS) wafer and an emission structure layer disposed on the CMOS wafer. The emission structure layer includes a first layer disposed on the CMOS wafer and including a plurality of first light emitting diodes which emit light having a first wavelength, and a second layer disposed on the first layer and including a plurality of second light emitting diodes which emit light having a second wavelength different from the first wavelength. Each of the plurality of first light emitting diodes includes a first emission structure and a first insulating layer which covers a side surface of the first emission structure. Each of the plurality of second light emitting diodes includes a second emission structure and a second insulating layer which covers a side surface of the second emission structure. The first insulating layer and the second insulating layer include different materials.

The first insulating layer may be in contact with the side surface of the first emission structure, and the second insulating layer may be in contact with the side surface of the second emission structure.

The first layer may further include a first planarization layer between at least the plurality of first light emitting diodes, and the second layer may further include a second planarization layer between at least the plurality of second light emitting diodes.

A first insulating material included in the first insulating layer may include a high-k dielectric material compared to a second insulating material included in the second insulating layer.

The first insulating material may include at least one of hafnium oxide, lanthanum oxide, zirconium oxide, tantalum oxide, hafnium oxynitride, zirconium oxynitride, tantalum oxynitride, hafnium nitride, lanthanum nitride, or zirconium nitride, and the second insulating material may include at least one of silicon oxide or aluminum oxide.

### BRIEF DESCRIPTION OF THE DRAWINGS

FIG. 1 is a schematic perspective view of a display device according to an embodiment of the disclosure.

FIG. 2 is a schematic cross-sectional view of a display device according to an embodiment of the disclosure.

FIGS. 3A and 3B are each a schematic plan view of a display device according to an embodiment of the disclosure.

FIG. 4 is a schematic perspective view illustrating in detail one light emitting diode included in a display device according to an embodiment.

FIG. 5 is an enlarged schematic plan view of a portion of a display device according to an embodiment of the disclosure.

FIG. 6 is an enlarged schematic cross-sectional view of a portion of a display device according to an embodiment of the disclosure.

FIGS. 7A to 7C are each a schematic plan view of some components of a display device according to an embodiment of the disclosure.

FIGS. 8A to 8C are each an enlarged schematic cross-sectional view of a portion of a display device according to an embodiment of the disclosure.

FIG. 9 is an enlarged schematic plan view of a portion of a display device according to an embodiment of the disclosure.

FIG. 10 is an enlarged schematic cross-sectional view of a portion of a display device according to an embodiment of the disclosure.

FIGS. 11A to 11C are each a schematic plan view of some components of a display device according to an embodiment of the disclosure.

FIG. 12 is a schematic block diagram of an electronic device according to one embodiment.

FIG. 13 is a schematic diagram of an electronic device according to various embodiments.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean in one or more standard deviations, or in ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In another embodiment, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

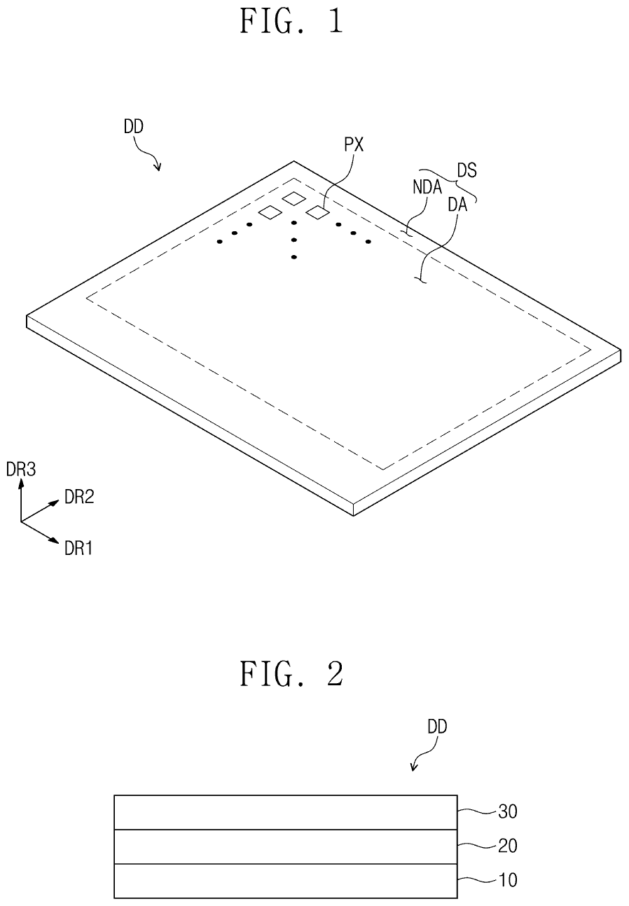

disposed (or directly disposed)disposed (or directly disposed)disposed (or directly disposed)FIG. 1 is a schematic perspective view of a display device according to an embodiment of the disclosure.

Referring to FIG. 1, a display device DD according to an embodiment of the disclosure may have a rectangular shape having long sides extending in a first direction DR1 and having short sides extending in a second direction DR2 crossing the first direction DR1. However, the display device DD is not limited thereto, and may have various shapes such as a circular shape or a polygonal shape. Hereinafter, a direction substantially perpendicularly crossing a plane defined by the first direction DR1 and the second direction DR2 is defined as a third direction DR3. In this disclosure, the meaning of “when viewed on a plane” or “in a plan view” is defined as being in a state when viewed in the third direction DR3.

A top surface of the display device DD may be defined as a display surface DS, and may have a plane defined by the first direction DR1 and the second direction DR2. Images generated in the display device DD may be provided for users through the display surface DS.

The display surface DS may include a display area DA and a non-display area NDA around the display area DA. The display area DA may display an image, and the non-display area NDA may not display an image. The non-display area NDA may surround the display area DA but is not limited thereto, and the non-display area NDA may not be disposed at one side of the display area DA.

Multiple pixels PX may be disposed in the display area DA. The pixels PX may be disposed in the form of a matrix. Each of the pixels PX may include a pixel circuit and a light emitting diode. All the pixels PX may generate light of the same color. The pixels PX may include multiple groups that generate light having different colors from each other.

FIG. 2 is a schematic cross-sectional view of a display device according to an embodiment of the disclosure. FIG. 2 illustrates an example of a cross-section of the display device DD illustrated in FIG. 1.

Referring to FIG. 2, the display device DD may include a circuit element layer 10, an emission structure layer 20, and a lens layer 30. However, the display device DD is not limited thereto, and in embodiment of the disclosure, the lens layer 30 may be omitted or another functional layer may be further added.

The circuit element layer 10 may include a pixel circuit. The pixel circuit may control an operation of a light emitting diode of the emission structure layer 20 to be described later. The pixel circuit may include at least one transistor. The circuit element layer 10 may include a complementary metal oxide semiconductor (CMOS) wafer. The CMOS wafer may include nMOSFET (NMOS) and pMOSFET (PMOS) which are complementarily connected. Multiple pixel areas are regularly arranged on the CMOS wafer, and the pixel circuit may be disposed in each of the pixel areas.

The emission structure layer 20 may include multiple light emitting diodes electrically connected to the pixel circuit. The light emitting diodes are a kind of compound semiconductors, and are electrically-powered light emitting diodes including gallium (Ga), phosphorus (P), and arsenic (As) as main semiconductor materials. In case that forward current is applied to a p-n junction structure, electrons and holes may be combined at a junction surface to generate light having a specific wavelength which corresponds to a band gap energy.

The lens layer 30 may be disposed on the emission structure layer 20, and include multiple lenses. The lens may be arranged to correspond to at least the light emitting diode. The lens may collect the light emitted from the light emitting diode. The light collected through the lens may be transmitted through a light guide unit.

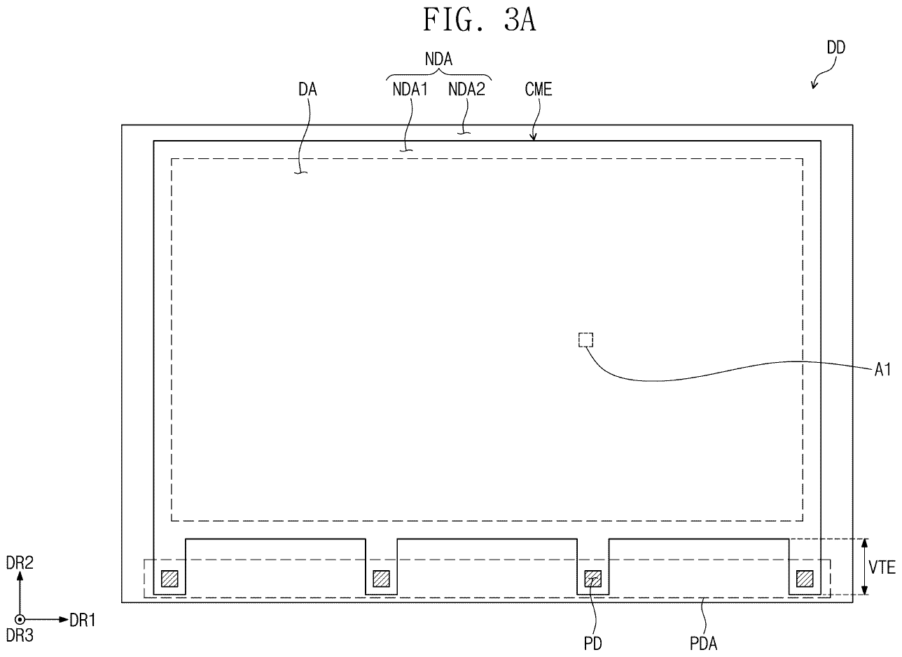

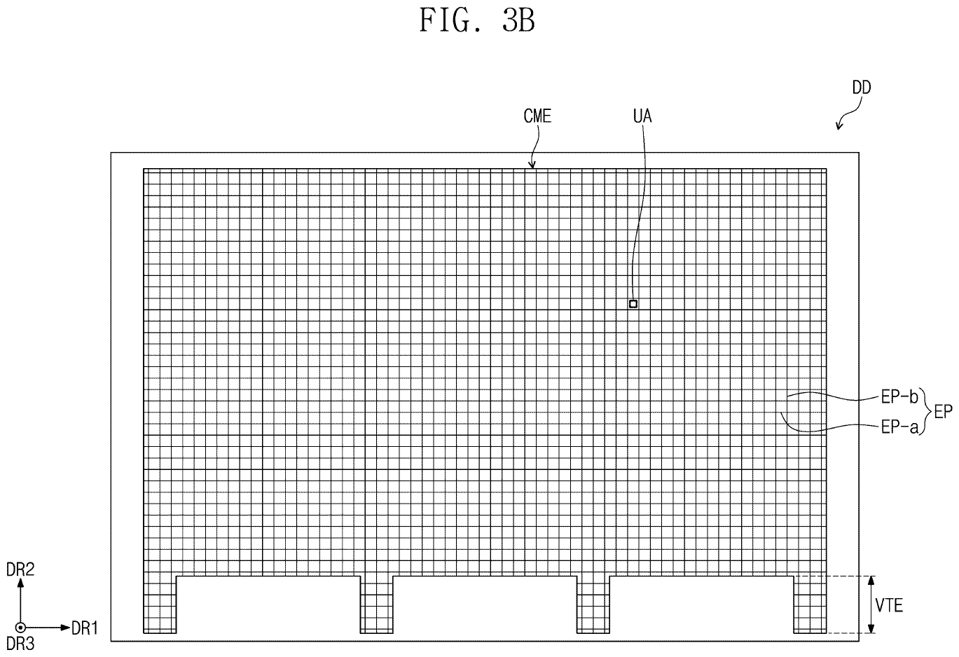

FIGS. 3A and 3B are each a schematic plan view of a display device according to an embodiment of the disclosure. FIG. 3A is a schematic plan view in which a common electrode CME is disposed in a display area DA and a non-display area NDA of a display device DD according to an embodiment of the disclosure. The display area DA and the non-display area NDA of the display device DD may also apply to the circuit element layer 10, i.e., the CMOS wafer, described with reference to FIG. 2. Hereinafter, the circuit element layer 10 will be described as a CMOS wafer 10, and designated by like reference symbol.

The common electrode CME may cover at least the display area DA. The common electrode CME transfers a power voltage, applied from the outside, to the entirety of the display area DA. Hereafter, the display area DA will be described as a first area DA, and designated by like reference symbol.

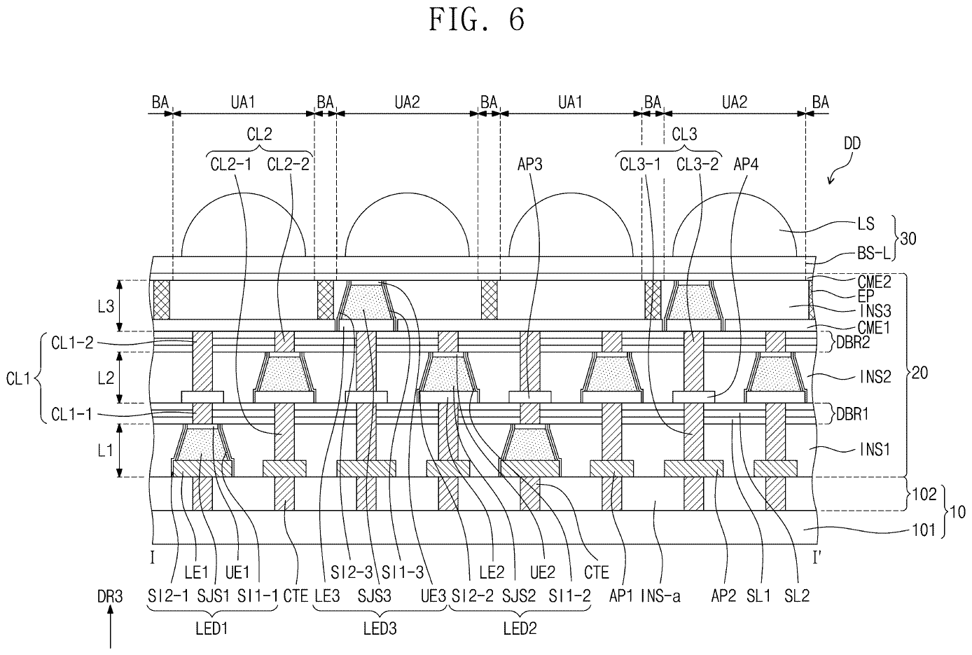

The display device DD according to an embodiment may include multiple common electrodes CME disposed at different layers. The display device DD may include a first common electrode CME1 (see FIG. 6) and a second common electrode CME2 (see FIG. 6), disposed at different layers, which will be described later, and the first common electrode CME1 (see FIG. 6) and the second common electrode CME2 (see FIG. 6) may be electrically connected to each other. This will be described later in detail.

The non-display area NDA may be divided into multiple areas. The non-display area NDA may include a second area NDA1 and a third area NDA2.

The second area NDA1 may be an area which is disposed outside the first area DA and in which dummy light emitting diodes are disposed. The second area NDA1 may surround the first area DA, but is not necessarily limited thereto. The dummy light emitting diodes may have the same stacked structure as light emitting diodes in the first area DA but may not be electrically connected to the common electrode CME, and thus the dummy light emitting diodes may not be driven (or emit light).

In case that the light emitting diodes are formed in a specific area through the same process, an outer area may have different process conditions from an inner area. For example, a deposited metal layer may have a smaller thickness, or an etch rate may be different. Accordingly, a defective light emitting diode may be formed in the outer area, and in light of this, the light emitting diode formed at the outer side is not used as a valid light emitting diode but used as a dummy light emitting diode. In case that process conditions and process efficiency are consistent regardless of areas, the dummy light emitting diodes may be omitted, and thus the second area NDA1 may be omitted in an embodiment of the disclosure.

Meanwhile, the dummy light emitting diode may not be disposed in a portion of the second area NDA1. In a portion of the second area NDA1, the common electrode CME may not be disposed, but the light emitting diode or the dummy light emitting diode may not be disposed. For example, the dummy light emitting diode may be disposed in an area, which is adjacent to the first area DA, of the second area NDA1, and the dummy light emitting diode may not be disposed in an area, which is adjacent to the third area NDA2, of the second area NDA1.

The third area NDA2 may be an area in which the common electrode CME is not disposed. The third area NDA2 may surround an entire edge of the second area NDA1, but is not necessarily limited thereto. Multiple driving circuits may be disposed in the third area NDA2 of the CMOS wafer 10 (see FIG. 2). For example, a scan driver may be disposed in each of a left area and a right area of the third area NDA2 with the first area DA disposed between the left area and the right area. A data driver may be disposed in a partial area of the third area NDA2, disposed at a lower side of the first area A1. An analog circuit such as a power circuit may be disposed in a partial area of the third area NDA2. The forgoing scan driver, data driver, and analog circuit may be embedded in the CMOS wafer. For example, the scan driver, the data driver, and the analog circuit may include transistors formed by the same method as the pixel circuit.

A pad area PDA in which multiple pad electrodes PD are disposed may be disposed on one side of the third area NDA2. The pad area PDA may correspond to a partial area of the third area NDA2. A circuit board may be electrically connected to the pad area PDA. FIG. 3A illustrates only four pad electrodes PD which receive the power voltage applied to the common electrode CME, but more pad electrodes PD may be disposed in the pad area PDA. The pad electrodes not illustrated may receive data image signals or control signals from the outside and provide the received signals to the data driver.

Referring to FIG. 3A, a voltage transfer electrode VTE may be disposed in the third area NDA2. Four voltage transfer electrodes VTE corresponding to the four pad electrodes PD are illustrated. The voltage transfer electrode VTE may extend from the common electrode CME toward the pad area PDA. The voltage transfer electrode VTE may be formed through the same process as the common electrode CME, have the same stacked structure as the common electrode CME, and have a shape of one body together with the common electrode CME. The voltage transfer electrode VTE and the common electrode CME may be different portions of one electrode formed through the same process.

FIG. 3B is a schematic plan view illustrating an arrangement relationship between each of a common electrode CME and a voltage transfer electrode VTE and an electrode pattern EP according to an embodiment of the disclosure.

The electrode pattern EP may overlap each of the common electrode CME and the voltage transfer electrode VTE. The electrode pattern EP may be disposed below the common electrode CME and the voltage transfer electrode VTE in the third direction DR3.

The electrode pattern EP may include multiple first lines EP-a extending in the first direction DR1 and multiple second lines EP-b extending in the second direction DR2. The first lines EP-a may be arranged in the second direction DR2, and the second lines EP-b may be arranged in the first direction DR1.

A unit area UA may be disposed in an area defined by the two most adjacent first lines EP-a among the first lines EP-a and the two most adjacent second lines EP-b among the second lines EP-b. The unit area UA may be disposed in the display area DA in FIG. 3A. FIG. 3B illustrates a unit area UA as representative. Multiple light emitting diodes may be disposed in the unit area UA.

A portion of the electrode pattern EP may overlap the common electrode CME, and the portion overlapping the common electrode CME may be electrically connected as a whole to the common electrode CME, thereby reducing a voltage drop generated in the common electrode CME. Another portion of the electrode pattern EP may overlap the voltage transfer electrode VTE, and the other portion overlapping the voltage transfer electrode VTE may be electrically connected as a whole to the voltage transfer electrode VTE, thereby reducing resistance of a voltage transfer path between the pad electrode PD (see FIG. 3A) and the common electrode CME. The electrode pattern EP may be formed through the same process regardless of areas, and have a shape of one body. The electrode pattern EP may electrically connect the foregoing first common electrode CME1 (see FIG. 6) and second common electrode CME2 (see FIG. 6) disposed at different layers.

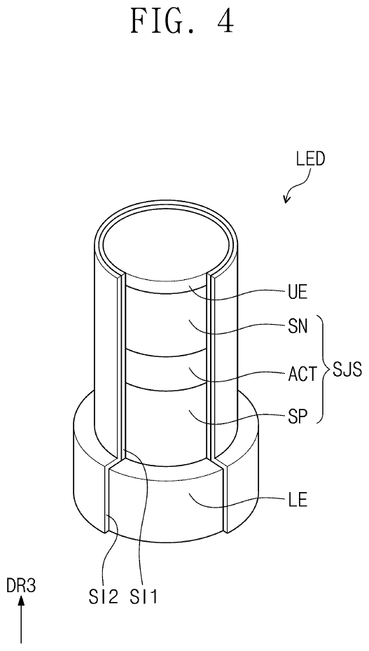

FIG. 4 is a schematic perspective view illustrating in detail one light emitting diode included in a display device according to an embodiment. A light emitting diode LED will be described in detail with reference to FIG. 4. Meanwhile, each of first to third light emitting diodes LED1, LED2, and LED3 (see FIG. 6) to be described later may have the stacked structure of the light emitting diode LED described with reference to FIG. 4.

The light emitting diode LED may have a pillar shape. The light emitting diode LED may have a size (or length) of a nanometer scale to a micrometer scale. The light emitting diode LED may have a diameter (or width) and/or length of a nanometer scale to a micrometer scale. The diameter (or width) may indicate a diameter (or width) in one direction perpendicular to the thickness direction DR3, and the length may indicate a length in the thickness direction DR3. However, the size of the light emitting diode LED is not limited thereto, and the size of the light emitting diode LED may be variously changed according to design conditions of all kinds of devices using, as a light source, a light emitting device using the light emitting diode LED.

FIG. 4 illustrates in brief a lower conductive pattern LE and an upper conductive pattern UE each having a single layer structure, and illustrates in detail an emission structure SJS. As an example, FIG. 4 illustrates the lower conductive pattern LE having a circular disc shape, and the emission structure SJS and the upper conductive pattern UE each having a cylindrical shape, but the shapes of the lower conductive pattern LE, the emission structure SJS, and the upper conductive pattern UE are not limited thereto. For example, each of the lower conductive pattern LE, the emission structure SJS, and the upper conductive pattern UE may have a polygonal column shape such as a quadrangular column shape.

The emission structure SJS may be a layer, which substantially performs a light emitting function, of the light emitting diode LED. The emission structure SJS may be described as an emission layer. The emission structure SJS may include an active layer ACT, a p-type semiconductor layer SP disposed at one side of the active layer ACT, and an n-type semiconductor layer SN disposed at the other side of the active layer ACT. Since the lower conductive pattern LE that is an anode is disposed below the active layer ACT, the p-type semiconductor layer SP may be disposed below the active layer ACT. Unlike the illustrated embodiment, in case that the upper conductive pattern UE disposed above the active layer ACT is an anode, the p-type semiconductor layer SP may be disposed on an upper side of the active layer ACT.

The active layer ACT may have a single-quantum well or multi-quantum well structure. Electron-hole pairs may be combined to emit light in response to an electric signal applied through the p-type semiconductor layer SP and the n-type semiconductor layer SN. The active layer ACT may emit light having a wavelength of about 400 nm to about 900 nm, and may use a double hetero-structure.

The active layer ACT may have a structure in which a semiconductor material having a large band gap energy and a semiconductor material having a small band gap energy are alternately stacked, and may include Groups III to V semiconductor materials selected according to a wavelength band of emitted light.

The p-type semiconductor layer SP may include at least one semiconductor material of InAlGaN, GaN, AlGaN, InGaN, AlN, or InN, and be doped with a first conductive dopant such as magnesium (Mg), zinc (Zn), calcium (Ca), or barium (Ba). For example, the p-type semiconductor layer SP may be p-GaN doped with magnesium (Mg). However, the material constituting the p-type semiconductor layer SP is not limited thereto, and other various materials may constitute the p-type semiconductor layer SP.

The n-type semiconductor layer SN may include at least one semiconductor material of InAlGaN, GaN, AlGaN, InGaN, AlN, or InN, and be doped with a second conductive dopant such as silicon (Si), germanium (Ge), or tin (Sn). However, the material constituting the n-type semiconductor layer SN is not limited thereto, and other various materials may constitute the n-type semiconductor layer SN.

Although not illustrated, the light emitting diode LED may further include a clad layer. The clad layer may be disposed above and/or below the active layer ACT. The clad layer may include an AlGaN layer or an InAlGaN layer. The light emitting diode LED may further include a tensile strain barrier reducing (TSBR) layer disposed above and/or below the active layer ACT. The TSBR layer may be a strain relief layer which is disposed between other semiconductor layers having different lattice structures and performs a buffer function to reduce a difference in lattice constant. The TSBR layer may include the p-type semiconductor layer such as p-GaInP, p-AlInP, or p-AlGaInP, but the disclosure is not limited thereto.

The lower conductive pattern LE may include at least one of a metal layer or a transparent conductive oxide layer. For example, the lower conductive pattern LE may include both the metal layer and the transparent conductive oxide layer. In another embodiment, the lower conductive pattern LE may include one of the metal layer and the transparent conductive oxide layer. The lower conductive pattern LE may further include a reflective layer. The lower conductive pattern LE may further include a functional layer disposed in each space between the metal layer, the transparent conductive oxide layer, and the reflective layer. The functional layer may be a layer which improves adhesion of each layer and prevents atomic diffusion of adjacent layers.

The metal layer may correspond to an adhesive layer which couples the CMOS wafer to a semiconductor substrate during a manufacture process for a display device. For example, the metal layer may be a layer in which a metal layer of the CMOS wafer and a metal layer of the semiconductor substrate are coupled to each other.

The metal layer may be provided as a single layer, or provided in plurality. The metal layer may include one of gold (Au), copper (Cu), silver (Ag), tin (Sn), titanium (Ti), zirconium (Zr), and tantalum (Ta), or include an alloy of two of the foregoing metals. In a case in which the metal layer is provided in plurality, the metal layers provided in plurality may have a structure in which sub-metal layers having different materials are alternately stacked.

The transparent conductive oxide layer may include indium tin oxide (ITO), indium zinc oxide (IZO), zinc oxide (ZnO), zinc tin oxide (ZTO), or indium gallium zinc oxide (IGZO). The transparent conductive oxide layer included in the lower conductive pattern LE may inject holes into the emission structure SJS.

The reflective layer may be a layer which reflects light, generated from the emission structure SJS, toward the emission structure SJS. The reflective layer may include gold (Au), copper (Cu), silver (Ag), titanium (Ti), or aluminum (Al).

The upper conductive pattern UE may include a transparent conductive oxide layer. The transparent conductive oxide layer may include indium tin oxide (ITO), indium zinc oxide (IZO), zinc oxide (ZnO), zinc tin oxide (ZTO), or indium gallium zinc oxide (IGZO). The transparent conductive oxide layer included in the upper conductive pattern UE may inject electrons into the emission structure SJS.

The upper conductive pattern UE may further include an electrode metal layer disposed between the emission structure SJS and the transparent conductive oxide layer including a transparent conductive oxide. The electrode metal layer may include a metal having a lower work function than the transparent conductive oxide layer. The electrode metal layer may improve an electron injection performance of the upper conductive pattern UE. The electrode metal layer may include aluminum (Al), titanium (Ti), indium (In), gold (Au), silver (Ag), nickel (Ni), copper (Cu), an oxide thereof, or an alloy thereof.

The light emitting diode LED may include an insulating layer SI1 which covers at least a portion of a side surface of the emission structure SJS. For convenience of explanation, FIG. 4 illustrates the insulating layer SI1, a portion of which is omitted, but the insulating layer SI1 may cover (or entirely cover) the side surface of the emission structure SJS. The insulating layer SI1 may cover the side surface of the emission structure SJS to prevent an etching surface from reducing efficiency during an etching process for forming the emission structure SJS. The insulating layer SI1 may cover at least the side surface of the emission structure SJS, and cover at least a portion of the upper conductive pattern UE and the lower conductive pattern LE.

The light emitting diode LED may further include an additional insulating layer SI2 disposed outside the insulating layer SI1. For convenience of explanation, FIG. 4 illustrates the additional insulating layer SI2, a portion of which is omitted, but the additional insulating layer SI2 may cover (or entirely cover) a side surface of the insulating layer SI1. The additional insulating layer SI2 may prevent the etching surface from reducing the efficiency and prevent contact between an external component and the light emitting diode LED. FIG. 4 illustrates only one additional insulating layer SI2, but the additional insulating layer SI2 may be provided as multiple layers that are two or more. The additional insulating layer SI2 may at least cover the side surface of the emission structure SJS, and cover at least a portion of the upper conductive pattern UE and the lower conductive pattern LE.

Although not illustrated, the light emitting diode LED may further include a side reflective layer disposed outside the additional insulating layer SI2. The side reflective layer may reflect the light generated from the light emitting diode LED so that the light generated from the light emitting diode LED is emitted upward, thereby increasing luminance efficiency. The side reflective layer may include gold, copper, silver, titanium, or aluminum.

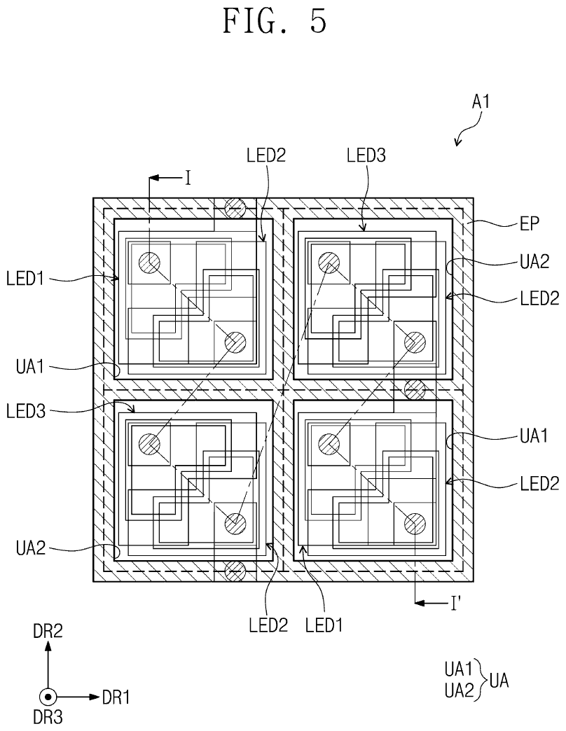

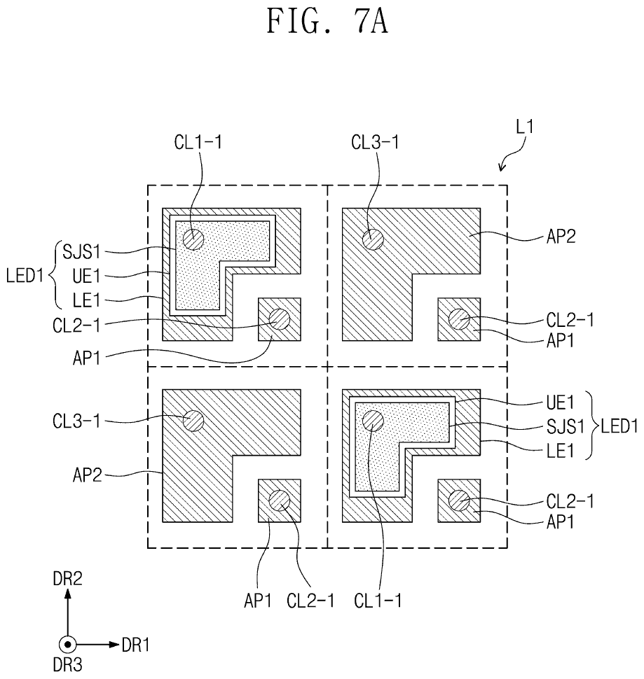

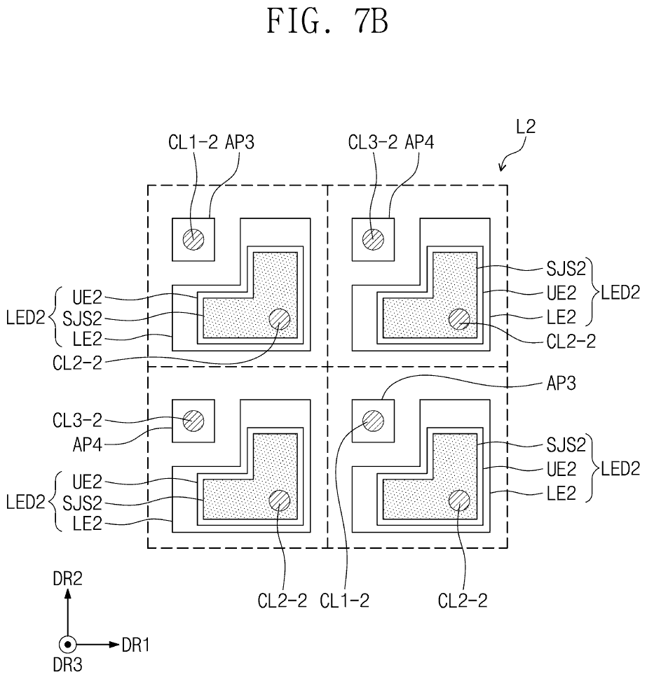

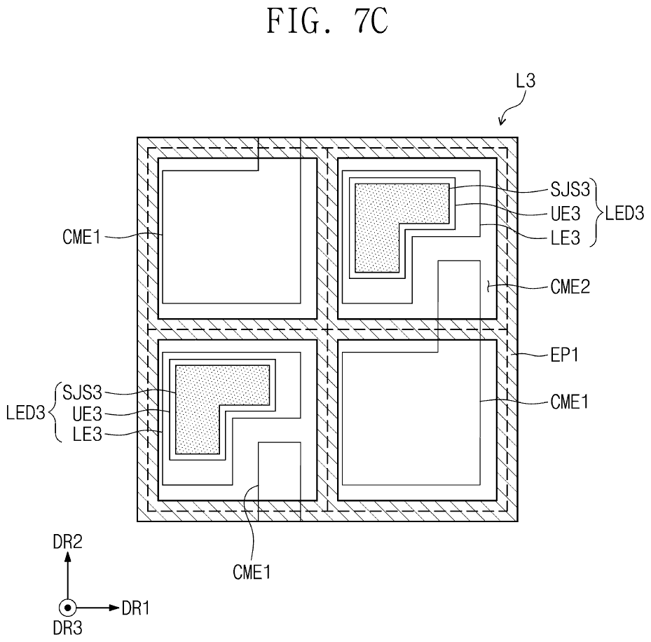

FIG. 5 is an enlarged schematic plan view of a portion of a display device according to an embodiment of the disclosure. FIG. 6 is an enlarged schematic cross-sectional view of a portion of a display device according to an embodiment of the disclosure. FIGS. 7A to 7C are each a schematic plan view of some components of a display device according to an embodiment of the disclosure. FIG. 5 is an enlarged plan view illustrating the partial area A1 of the first area DA illustrated in FIG. 3. FIG. 6 is a schematic cross-sectional view corresponding to cutting line I-I′ illustrated in FIG. 5. FIGS. 7A to 7C are schematic plan views respectively illustrating planar arrangements of components arranged to correspond to the first layer L1, the second layer L2, and the third layer L3 among the components illustrated in FIG. 5.

Referring to FIG. 5, the first area DA may include multiple unit areas UA and a boundary area BA disposed between the unit areas UA. The boundary area BA may be an area overlapping the electrode pattern EP described above.

Multiple light emitting diodes LED1, LED2, and LED3 are disposed in each of the unit areas UA. The unit areas UA may include a first unit area UA1 overlapped by a first light emitting diode LED1 and a second light emitting diode LED2, and a second unit area UA2 overlapped by the second light emitting diode LED2 and a third light emitting diode LED3. The first light emitting diode LED1, the second light emitting diode LED2, and the third light emitting diode LED3 may be disposed at different layers, and two or more light emitting diodes may be arranged to correspond to each of the unit areas UA. The first unit area UA1 and the second unit area UA2 may be alternately disposed along each of the first direction DR1 and the second direction DR2.

Referring to FIGS. 5 to 7C together, a display device DD according to an embodiment may include a CMOS wafer 10, an emission structure layer 20, and a lens layer 30.

The CMOS wafer 10 may include a silicon substrate 101. The silicon substrate 101 may include source/drain regions and a gate, which define a transistor. Shallow trench isolation (STI) regions which isolate the transistor and prevent leakage current may be defined in the silicon substrate 101.

The CMOS wafer 10 may further include a contact layer 102 disposed on the silicon substrate 101. In the first area DA, the contact layer 102 may include multiple contact electrodes CTE. The contact electrodes CTE may be electrically connected to the source/drain regions of the silicon substrate 101. The contact electrodes CTE may be formed through a damascene process. The contact electrodes CTE may include metals such as copper or tungsten. The contact electrodes CTE may include a tungsten structure, a titanium layer which surrounds a side surface and a bottom surface of the tungsten structure, and a titanium nitride layer which surrounds the titanium layer. In another embodiment, the contact electrodes CTE may include a copper structure, a tantalum layer which surrounds a side surface and a bottom surface of the copper structure, and a tantalum nitride layer which surrounds the tantalum layer.

The contact layer 102 may include a lower insulating layer INS-a disposed on the silicon substrate 101. The lower insulating layer INS-a may include an oxide layer such as a silicon oxide layer, a silicon nitride layer, a silicon oxynitride layer, or an aluminum oxide layer. The lower insulating layer INS-a that is a single layer is illustrated, but the lower insulating layer INS-a may be provided as multiple layers. Respective top surfaces of the contact electrodes CTE may define the same plane (or flat surface) together with a top surface of the lower insulating layer INS-a.

The emission structure layer 20 may be disposed on the CMOS wafer 10, and include multiple layers L1, L2, and L3. In the first area DA, multiple layers L1, L2, and L3 may include multiple light emitting diodes LED1, LED2, and LED3, respectively. Multiple light emitting diodes LED1, LED2, and LED3 may include multiple first light emitting diodes LED1, multiple second light emitting diodes LED2, and multiple third light emitting diodes LED3, which are disposed at different layers. However, unlike the embodiment illustrated in FIG. 6, the stacking sequence of a first layer L1 including the first light emitting diodes LED1, a second layer L2 including the second light emitting diodes LED2, and a third layer L3 including the third light emitting diodes LED3 may be changed.

The first layer L1 may be disposed on the contact layer 102 of the CMOS wafer 10, and include multiple first light emitting diodes LED1. Multiple first light emitting diodes LED1 may be arranged to correspond to the first unit area UA1. Multiple first light emitting diodes LED1 may be emit light having a first wavelength.

Each of the first light emitting diodes LED1 may include a first emission structure SJS1 and a first insulating layer SI1-1 disposed on a side surface of the first emission structure SJS1. Each of the first light emitting diodes LED1 may further include a first lower conductive pattern LE1 disposed below the first emission structure SJS1, and a first upper conductive pattern UE1 disposed above the first emission structure SJS1. Each of the first light emitting diodes LED1 may further include a first additional insulating layer SI2-1 disposed outside the first insulating layer SI1-1.

The first lower conductive pattern LE1 may be disposed (or directly disposed) on the contact layer 102. The first lower conductive pattern LE1 may be in contact (or in direct contact) with each of the contact electrodes CTE of the contact layer 102. The first lower conductive pattern LE1 may include at least a metal. The first lower conductive pattern LE1 may include a metal layer. The metal layer of the first lower conductive pattern LE1 may be provided to electrically connect the contact electrode CTE of the CMOS wafer 10 to the first lower conductive pattern LE1. The first lower conductive pattern LE1 may further include a transparent conductive oxide layer.

The first emission structure SJS1 may be disposed on the first lower conductive pattern LE1 and include at least an active layer. The first emission structure SJS1 may have a planar area smaller than or the same as that of the first lower conductive pattern LE1 disposed below the first emission structure SJS1. The first emission structure SJS1 may overlap (or entirely overlap) the first lower conductive pattern LE1. As illustrated in FIG. 6, the side surface of the first emission structure SJS1 may be inclined on the basis of the thickness direction DR3. The side surface of the first emission structure SJS1 may not be perpendicular to a top surface of the first lower conductive pattern LE1 of the first emission structure SJS1. For example, the length of the top surface of the first emission structure SJS1 may be smaller the length of the bottom surface of the first emission structure SJS1. The first emission structure SJS1 may be formed through a dry etching process, and include a side surface not parallel to the thickness direction DR3.

The first upper conductive pattern UE1 may be disposed on the first emission structure SJS1 and include a transparent conductive oxide. The first upper conductive pattern UE1 may overlap (or entirely overlap) the first emission structure SJS1. The first upper conductive pattern UE1 may have a planar area smaller than or the same as that of the first emission structure SJS1.

The first insulating layer SI1-1 may cover (or entirely cover) the side surface of the first emission structure SJS1. The first insulating layer SI1-1 may cover the side surface of the first emission structure SJS1 to prevent an etching surface from reducing efficiency during an etching process for forming the first emission structure SJS1. The first insulating layer SI1-1 may cover at least the side surface of the first emission structure SJS1, and cover at least a portion of the first upper conductive pattern UE1 and the first lower conductive pattern LE1.

The first light emitting diode LED1 may further include the first additional insulating layer SI2-1 disposed outside the first insulating layer SI1-1. The first additional insulating layer SI2-1 may cover (or entirely cover) a side surface of the first insulating layer SI1-1. The first additional insulating layer SI2-1 may be provided as multiple layers that are two or more. The first additional insulating layer SI2-1 may cover at least the side surface of the first emission structure SJS1, and cover at least a portion of the first upper conductive pattern UE1 and the first lower conductive pattern LE1.

The first layer L1 may further include first-layer additional conductive patterns AP1 and AP2. The first-layer additional conductive patterns AP1 and AP2 may be respectively in contact (or in direct contact) the contact electrodes CTE of the contact layer 102, and be provided to electrically connect the second light emitting diodes LED2 and the third light emitting diodes LED3, disposed above the first-layer additional conductive patterns AP1 and AP2, to the CMOS wafer 10. The first-layer additional conductive patterns AP1 and AP2 may be disposed at the same layer as the first lower conductive pattern LE1. The first-layer additional conductive patterns AP1 and AP2 may be formed through the same process as the first lower conductive pattern LE1, and include the same stacked structure and the same material as the first lower conductive pattern LE1. The first-layer additional conductive patterns AP1 and AP2 may include a first additional conductive pattern AP1 overlapping each of the second light emitting diodes LED2 in the third direction DR3, and a second additional conductive pattern AP2 overlapping each of the third light emitting diodes LED3 in the third direction DR3.

The second layer L2 may be disposed on the first layer L1, and may include multiple second light emitting diodes LED2. Multiple second light emitting diodes LED2 may be arranged to correspond to both the first unit area UA1 and the second unit area UA2. Multiple second light emitting diodes LED2 may emit light having a second wavelength different from the first wavelength.

On a unit area, the number of the arranged second light emitting diodes LED2 may be twice the number of the arranged first light emitting diodes LED1. As illustrated in FIG. 5, in case that an area including two first unit areas UA1 and two second unit areas UA2 is defined as a unit surface area, two first light emitting diodes LED1 and four second light emitting diodes LED2 may be disposed in the unit surface area.

Each of the second light emitting diodes LED2 may include a second emission structure SJS2 and a second insulating layer SI1-2 disposed on a side surface of the second emission structure SJS2. Each of the second light emitting diodes LED2 may further include a second lower conductive pattern LE2 disposed below the second emission structure SJS2, and a second upper conductive pattern UE2 disposed above the second emission structure SJS2. Each of the second light emitting diodes LED2 may further include a second additional insulating layer SI2-2 disposed outside the second insulating layer SI1-2.

The second lower conductive pattern LE2 may include a transparent conductive oxide. The second lower conductive pattern LE2 may not include a metal. Unlike the first lower conductive pattern LE1, the second lower conductive pattern LE2 may not include the metal but include only the transparent conductive oxide. The second lower conductive pattern LE2 may include only the transparent conductive oxide in order not to block light generated from the first light emitting diode LED1 disposed below the second lower conductive pattern LE2.

The second emission structure SJS2 may be disposed on the second lower conductive pattern LE2 and include at least an active layer. The second emission structure SJS2 may have a planar area smaller than or the same as that of the second lower conductive pattern LE2 disposed below the second emission structure SJS2. The second emission structure SJS2 may overlap (or entirely overlap) the second lower conductive pattern LE2. As illustrated in FIG. 6, the side surface of the second emission structure SJS2 may be inclined on the basis of the thickness direction DR3. The side surface of the second emission structure SJS2 may not be perpendicular to a top surface of the second lower conductive pattern LE2 of the second emission structure SJS2. For example, the length of the top surface of the second emission structure SJS2 may be smaller the length of the bottom surface of the second emission structure SJS2. The second emission structure SJS2 may be formed through a dry etching process, and include a side surface not parallel to the thickness direction DR3.

The second upper conductive pattern UE2 may be disposed on the second emission structure SJS2 and include a transparent conductive oxide. The second upper conductive pattern UE2 may overlap (or entirely overlap) the second emission structure SJS2. The second upper conductive pattern UE2 may have a planar area smaller than or the same as that of the second emission structure SJS2.

The second insulating layer SI1-2 may cover (or entirely cover) the side surface of the second emission structure SJS2. The second insulating layer SI1-2 may cover the side surface of the second emission structure SJS2 to prevent an etching surface from reducing the efficiency during an etching process for forming the second emission structure SJS2. The second insulating layer SI1-2 may cover at least the side surface of the second emission structure SJS2, and cover at least a portion of the second upper conductive pattern UE2 and the second lower conductive pattern LE2.

The second light emitting diode LED2 may further include the second additional insulating layer SI2-2 disposed outside the second insulating layer SI1-2. The second additional insulating layer SI2-2 may cover (or entirely cover) a side surface of the second insulating layer SI1-2. The second additional insulating layer SI2-2 may be provided as multiple layers that are two or more. The second additional insulating layer SI2-2 may cover at least the side surface of the second emission structure SJS2, and cover at least a portion of the second upper conductive pattern UE2 and the second lower conductive pattern LE2.

A planar area of each of multiple second light emitting diodes LED2 may be larger than or the same as a planar area of each of multiple first light emitting diodes LED1. A planar area of each of the second emission structures SJS2 included in the second light emitting diodes LED2 may be larger than or the same as a planar area of each of the first emission structures SJS2 included in the first light emitting diodes LED1.

The second layer L2 may further include second-layer additional conductive patterns AP3 and AP4. The second-layer additional conductive patterns AP3 and AP4 may be provided for an electrical connection between a first common electrode CME1 and the first light emitting diodes LED1 disposed below the second-layer additional conductive patterns AP3 and AP4, and an electrical connection between the CMOS wafer 10 and the third light emitting diodes LED3 disposed above the second-layer additional conductive patterns AP3 and AP4. The second-layer additional conductive patterns AP3 and AP4 may be disposed at the same layer as the second lower conductive pattern LE2. The second-layer additional conductive patterns AP3 and AP4 may be formed through the same process as the second lower conductive pattern LE2, and include the same stacked structure and the same material as the second lower conductive pattern LE2. The second-layer additional conductive patterns AP3 and AP4 may include a third additional conductive pattern AP3 overlapping each of the first light emitting diodes LED1 in the third direction DR3, and a fourth additional conductive pattern AP4 overlapping each of the third light emitting diodes LED3 in the third direction DR3.

The third layer L3 may be disposed on the second layer L2, and may include multiple third light emitting diodes LED3. Multiple third light emitting diodes LED3 may be arranged to correspond to the second unit area UA2. Multiple third light emitting diodes LED3 may emit light having a third wavelength different from the first wavelength and the second wavelength.

On a unit area, the number of the arranged second light emitting diodes LED2 may be twice the number of the arranged third light emitting diodes LED3. As illustrated in FIG. 5, in case that an area including two first unit areas UA1 and two second unit areas UA2 is defined as a unit surface area, two third light emitting diodes LED3 and four second light emitting diodes LED2 may be disposed in the unit surface area.

Each of the third light emitting diodes LED3 may include a third emission structure SJS3 and a third insulating layer SI1-3 disposed on a side surface of the third emission structure SJS3. Each of the third light emitting diodes LED3 may further include a third lower conductive pattern LE3 disposed below the third emission structure SJS3, and a third upper conductive pattern UE3 disposed above the third emission structure SJS3. Each of the third light emitting diodes LED3 may further include a third additional insulating layer SI2-3 disposed outside the third insulating layer SI1-3.

The third lower conductive pattern LE3 may include a transparent conductive oxide. The third lower conductive pattern LE3 may not include a metal. Unlike the first lower conductive pattern LE1, the third lower conductive pattern LE3 may not include the metal but include only the transparent conductive oxide. The third lower conductive pattern LE3 may include only the transparent conductive oxide in order not to block light generated from the first light emitting diode LED1 and the second light emitting diode LED2, disposed below the third lower conductive pattern LE3.

The third emission structure SJS3 may be disposed on the third lower conductive pattern LE3 and include at least an active layer. The third emission structure SJS3 may have a planar area smaller than or the same as that of the third lower conductive pattern LE3 disposed below the third emission structure SJS3. The third emission structure SJS3 may overlap (or entirely overlap) the third lower conductive pattern LE3. As illustrated in FIG. 6, the side surface of the third emission structure SJS3 may be inclined on the basis of the thickness direction DR3. The side surface of the third emission structure SJS3 may not be perpendicular to a top surface of the third lower conductive pattern LE3 of the third emission structure SJS3. For example, the length of the top surface of the third emission structure SJS3 may be smaller the length of the bottom surface of the third emission structure SJS3. The third emission structure SJS3 may be formed through a dry etching process, and include a side surface not parallel to the thickness direction DR3.

The third upper conductive pattern UE3 may be disposed on the third emission structure SJS3 and include a transparent conductive oxide. The third upper conductive pattern UE3 may overlap (or entirely overlap) the third emission structure SJS3. The third upper conductive pattern UE3 may have a planar area smaller than or the same as that of the third emission structure SJS3.

The third insulating layer SI1-3 may cover (or entirely cover) the side surface of the third emission structure SJS3. The third insulating layer SI1-3 may cover the side surface of the third emission structure SJS3 to prevent an etching surface from reducing the efficiency during an etching process for forming the third emission structure SJS3. The third insulating layer SI1-3 may cover at least the side surface of the third emission structure SJS3, and cover at least a portion of the third upper conductive pattern UE3 and the third lower conductive pattern LE3.

The third light emitting diode LED3 may further include the third additional insulating layer SI2-3 disposed outside the third insulating layer SI1-3. The third additional insulating layer SI2-3 may cover (or entirely cover) a side surface of the third insulating layer SI1-3. The third additional insulating layer SI2-3 may be provided as multiple layers that are two or more. The third additional insulating layer SI2-3 may cover at least the side surface of the third emission structure SJS3, and cover at least a portion of the third upper conductive pattern UE3 and the third lower conductive pattern LE3.

A planar area of each of multiple third light emitting diodes LED3 may be larger than or the same as a planar area of each of multiple second light emitting diodes LED2. A planar area of each of the third emission structures SJS3 included in the third light emitting diodes LED3 may be larger than or the same as a planar area of each of the second emission structures SJS2 included in the second light emitting diodes LED2.

The emission structure layer 20 may include planarization layers INS1, INS2, and INS3 disposed between at least some of multiple light emitting diodes LED1, LED2, and LED3. The first layer L1 may further include a first planarization layer INS1 disposed between at least the first light emitting diodes LED1. The second layer L2 may further include a second planarization layer INS2 disposed between at least the second light emitting diodes LED2. The third layer L3 may further include a third planarization layer INS3 disposed between at least the third light emitting diodes LED3.

The first planarization layer INS1 may overlap the unit areas UA and the boundary area BA, and fill an area in which the first light emitting diodes LED1 are not disposed. The first planarization layer INS1 may include an organic material. A top surface of the first planarization layer INS1 may define the same plane (or flat surface) together with the top surface of the first upper conductive pattern UE1 of the first light emitting diodes LED1. The second planarization layer INS2 may overlap the unit areas UA and the boundary area BA, and fill an area in which the second light emitting diodes LED2 are not disposed. The second planarization layer INS2 may include an organic material. A top surface of the second planarization layer INS2 may define the same plane (or flat surface) together with the top surface of the second upper conductive pattern UE2 of the second light emitting diodes LED2. The third planarization layer INS3 may overlap the unit areas UA and the boundary area BA, and fill an area in which the third light emitting diodes LED3 are not disposed. The third planarization layer INS3 may include an organic material. A top surface of the third planarization layer INS3 may define the same plane (or flat surface) together with the top surface of the third upper conductive pattern UE3 of the third light emitting diodes LED3.

The emission structure layer 20 may include the common electrodes CME1 and CME2 electrically connected to at least a portion of multiple light emitting diodes LED1, LED2, and LED3. The common electrodes CME1 and CME2 may include a first common electrode CME1 and a second common electrode CME2. The first common electrode CME1 may be electrically connected to at least a portion of the first light emitting diodes LED1, the second light emitting diodes LED2, and the third light emitting diodes LED3. The second common electrode CME2 may be electrically connected to at least a portion of the remainder, which is not electrically connected to the first common electrode CME1, of the first light emitting diodes LED1, the second light emitting diodes LED2, and the third light emitting diodes LED3. In the display device DD according to an embodiment illustrated in FIGS. 5 to 7C, the first common electrode CME1 may be electrically connected to the first light emitting diodes LED1 and the second light emitting diodes LED2, and the second common electrode CME2 may be electrically connected to the third light emitting diodes LED3.

The first common electrode CME1 may be disposed at the same layer as the third lower conductive pattern LE3. The first common electrode CME1 may be formed through the same process as the third lower conductive pattern LE3, and include the same stacked structure and the same material as the third lower conductive pattern LE3. The first common electrode CME1 may include a transparent conductive oxide. The second common electrode CME2 may be disposed on the third layer L3. The second common electrode CME2 may include a transparent conductive oxide.

The emission structure layer 20 may further include an electrode pattern EP, and the electrode pattern EP has a mesh structure in a plan view. The electrode pattern EP may be arranged to correspond to the boundary area BA. The electrode pattern EP may be disposed between the first common electrode CME1 and second common electrode CME2. The electrode pattern EP may not overlap each of the first light emitting diodes LED1, the second light emitting diodes LED2, and the third light emitting diodes LED3 in a plan view.

The electrode pattern EP may be disposed in the third layer L3, and electrically connects the first common electrode CME1 to the second common electrode CME2. The electrode pattern EP may be disposed at the same layer as the third emission structure SJS3 of the third light emitting diode LED3. The electrode pattern EP may be in contact (or in direct contact) a top surface of the first common electrode CME1 and a bottom surface of the second common electrode CME2, and electrically connect the first common electrode CME1 to the second common electrode CME2.

The emission structure layer 20 may further include optical layers DBR1 and DBR2. The optical layers DBR1 and DBR2 may be disposed in at least one of a space between the first layer L1 and the second layer L2 or a space between the second layer L2 and the third layer L3. The optical layers DBR1 and DBR2 may include, for example, a first optical layer DBR1 disposed between the first layer L1 and the second layer L2, and a second optical layer DBR2 disposed between the second layer L2 and the third layer L3. Any one of the first optical layer DBR1 and the second optical layer DBR2 may be omitted.

Each of the first optical layer DBR1 and the second optical layer DBR2 may include multiple sub-layers SL1 and SL2. Each of the first optical layer DBR1 and the second optical layer DBR2 may include a first sub-layer SL1 having a first refractive index, and a second sub-layer SL2 having a second refractive index different from the first refractive index. The first sub-layer SL1 and the second sub-layer SL2 may be each provided in plurality, and be alternately disposed. As having a structure in which the first sub-layer SL1 and the second sub-layer SL2, having different refractive indexes, are alternately disposed, each of the first optical layer DBR1 and the second optical layer DBR2 may reflect light having a specific wavelength and transmit light having other wavelengths. For example, the first optical layer DBR1 may transmit light having a wavelength, emitted from the first light emitting diode LED1, and reflect light having wavelengths, emitted from the second light emitting diode LED2 and the third light emitting diode LED3. The second optical layer DBR2 may transmit the light having the wavelengths, emitted from the first light emitting diode LED1 and the second light emitting diode LED2, and reflect the light having the wavelength, emitted from the third light emitting diode LED3.

The emission structure layer 20 may further include connection lines CL1, CL2, and CL3. The connection lines CL1, CL2, and CL3 may be respectively provided to electrically connect the light emitting diodes LED1, LED2, and LED3 to the first common electrode CME1 and the CMOS wafer. Each of the connection lines CL1, CL2, and CL3 may be formed through the damascene process. Each of the connection lines CL1, CL2, and CL3 may include a metal such as copper or tungsten.

A first connection line CL1 may be disposed on each of the first light emitting diodes LED1. The first connection lines CL1 may overlap the first light emitting diodes LED1 in a plan view, and be provided to electrically connect the first common electrodes CME1 to the first light emitting diodes LED1. The first connection line CL1 may include a (1-1)-th connection line CL1-1 disposed between the first upper conductive pattern UE1 of the first light emitting diode LED1 and the third additional conductive pattern AP3, and a (1-2)-th connection line CL1-2 disposed between the third additional conductive pattern AP3 and the first common electrode CME1. The first lower conductive pattern LE1 of the first light emitting diode LED1 may be in direct contact with the contact electrode CTE and electrically connected to the CMOS wafer 10. The first upper conductive pattern UE1 of the first light emitting diode LED1 may be electrically connected to the first common electrode CME1 through the (1-1)-th connection line CL1-1, the third additional conductive pattern AP3, and the (1-2)-th connection line CL1-2 which are disposed, in sequence, between the first upper conductive pattern UE1 and the first common electrode CME1.

Second connection lines CL2 may be disposed above and below each of the second light emitting diodes LED2. The second connection lines CL2 may overlap the second light emitting diode LED2 in a plan view, and be provided to electrically connect the first common electrode CME1 and the CMOS wafer 10 to the second light emitting diode LED2. The second connection lines CL2 may include a (2-1)-th connection line CL2-1 disposed between the second lower conductive pattern LE2 of the second light emitting diode LED2 and the first additional conductive pattern AP1, and a (2-2)-th connection line CL2-2 disposed between the second upper conductive pattern UE2 of the second light emitting diode LED2 and the first common electrode CME1. The second lower conductive pattern LE2 of the second light emitting diode LED2 may be electrically connected to the CMOS wafer 10 through the (2-1)-th connection line CL2-1 and the first additional conductive pattern AP1 which are disposed, in sequence, between the second lower conductive pattern LE2 and the CMOS wafer 10. The second upper conductive pattern UE2 of the second light emitting diode LED2 may be electrically connected to the first common electrode CME1 through the (2-2)-th connection line CL2-2 disposed between the second upper conductive pattern UE2 and the first common electrode CME1.

A third connection line CL3 may be disposed below each of the third light emitting diodes LED3. The third connection line CL3 may overlap the third light emitting diode LED3 in a plan view, and be provided to electrically connect the CMOS wafer 10 to the third light emitting diode LED3. The third connection line CL3 may include a (3-1)-th connection line CL3-1 disposed between the third lower conductive pattern LE3 of the third light emitting diode LED3 and the fourth additional conductive pattern AP4, and a (3-2)-th connection line CL3-2 disposed between the fourth additional conductive pattern AP4 and the second additional conductive pattern AP2. The third upper conductive pattern UE3 of the third light emitting diode LED3 may be in direct contact with the second common electrode CME2 and electrically connected to the second common electrode CME2. The third lower conductive pattern LE3 of the third light emitting diode LED3 may be electrically connected to the CMOS wafer 10 through the (3-1)-th connection line CL3-1, the fourth additional conductive pattern AP4, the (3-2)-th connection line CL3-2, and the second additional conductive pattern AP2 which are disposed, in sequence, between the third lower conductive pattern LE3 and the CMOS wafer 10.

The first light emitting diodes LED1, the second light emitting diodes LED2, and the third light emitting diodes LED3 may not at least partially overlap each other in a plan view. In a plan view, a portion of each of the first light emitting diodes LED1 may overlap the second light emitting diode LED2, and the remaining portion may not overlap the second light emitting diode LED2. Each of the first light emitting diodes LED1 may not overlap the third light emitting diode LED3 in a plan view. In a plan view, a portion of each of the second light emitting diodes LED2 may overlap each of the first light emitting diode LED1 and the third light emitting diode LED3, and the remaining portion may not overlap each of the first light emitting diode LED1 and the third light emitting diode LED3. In a plan view, a portion of each of the third light emitting diodes LED3 may overlap the second light emitting diode LED2, and the remaining portion may not overlap the second light emitting diode LED2. The first light emitting diodes LED1, the second light emitting diodes LED2, and the third light emitting diodes LED3 may not overlap other light emitting diodes on areas electrically connected to the connection lines CL1, CL2, and CL3, respectively.

The lens layer 30 may be disposed on the emission structure layer 20 and include multiple lenses LS. The lens layer 30 may further include a passivation layer BS-L which provides a base surface on which the lenses LS are disposed. The passivation layer BS-L may be disposed on the second common electrode CME2 to protect the second common electrode CME2. The passivation layer BS-L may include an organic material or an inorganic material.

The lenses LS may be arranged to overlap at least the light emitting diodes LED1, LED2, and LED3 in the third direction DR3. As illustrated in FIG. 6, the lenses LS may be arranged to correspond to the first unit area UA1 and the second unit area UA2, respectively. The lenses LS may be provided in one per first unit area UA1, and provided in one per second unit area UA2. The lens LS provided in the first unit area UA1 may be arranged to correspond to one first light emitting diode LED1 and one second light emitting diode LED2, and the lens LS provided in the second unit area UA2 may be arranged to correspond to one second light emitting diode LED2 and one third light emitting diode LED3. Each of the lenses LS may have a circular shape in a plan view, and a diameter of each of the lenses LS may be 1 micrometer or less.

The display device DD according to an embodiment may have a structure in which the light emitting diodes LED1, LED2, and LED3 are provided in multiple layers, thereby having high resolution. Meanwhile, due to the high resolution of the display device DD according to an embodiment, a voltage drop may greatly occur at the common electrode. However, the display device DD according to an embodiment may include the first common electrode CME1 and the second common electrode CME2, which are provided in multiple layers, and have a structure in which the first common electrode CME1 and the second common electrode CME2 are electrically connected to each other through the electrode pattern EP, thereby reducing the voltage drop occurring at the common electrode. Accordingly, the resolution of the display device DD may be improved, and defects may be reduced.

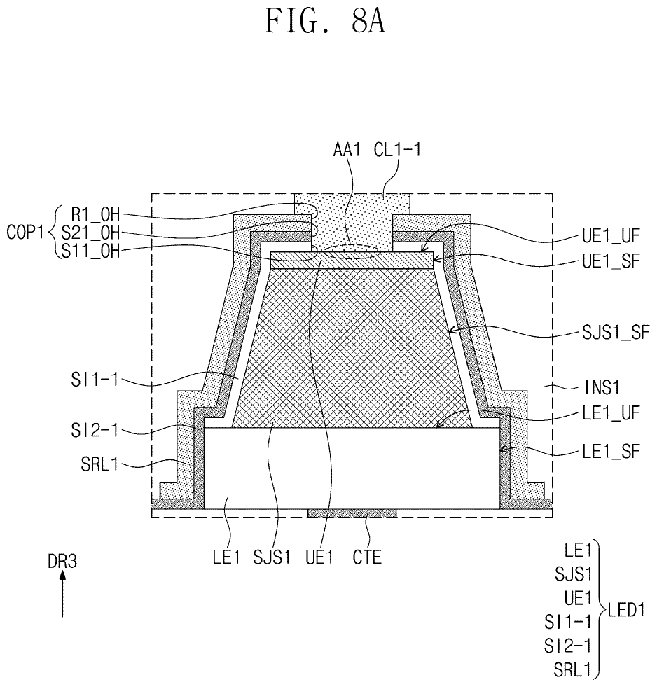

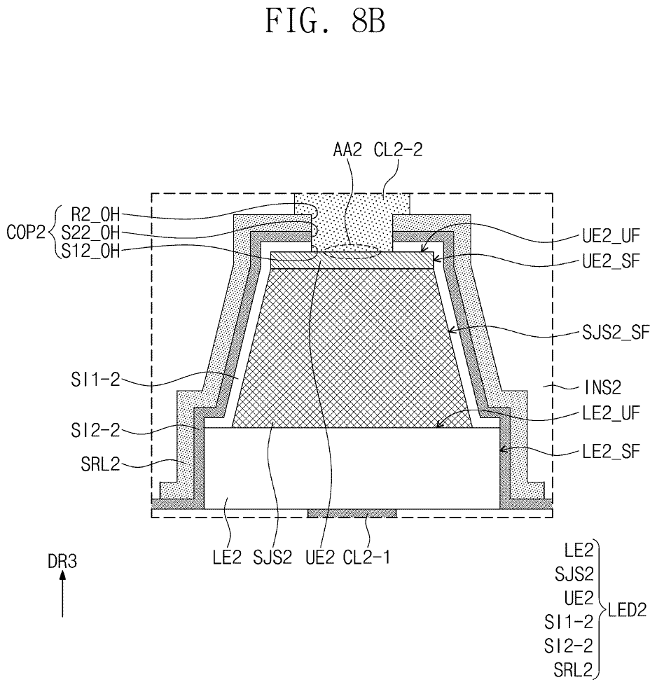

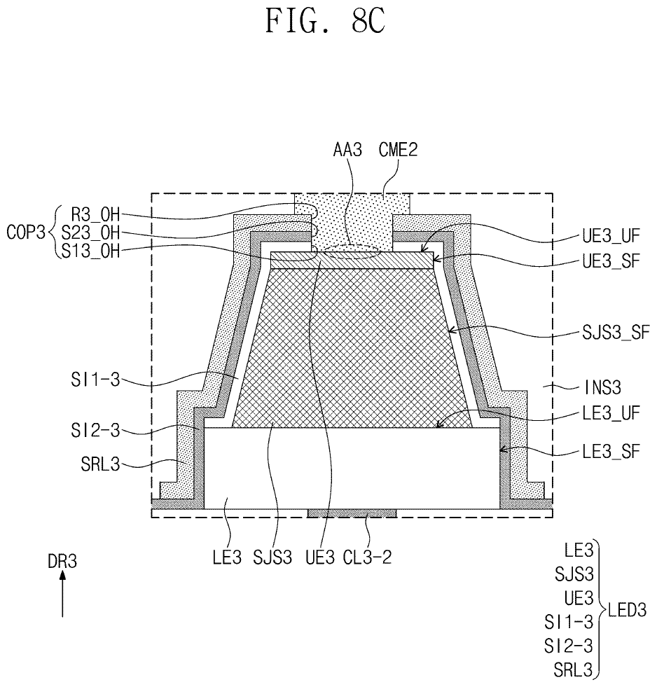

FIGS. 8A to 8C are each an enlarged schematic cross-sectional view of a portion of a display device according to an embodiment of the disclosure. FIG. 8A is a schematic cross-sectional view illustrating mainly a cross-section of a first light emitting diode LED1 included in a display device DD according to an embodiment. FIG. 8A is a schematic cross-sectional view illustrating mainly a cross-section of a second light emitting diode LED2 included in the display device DD according to an embodiment. FIG. 8C is a schematic cross-sectional view illustrating mainly a cross-section of a third light emitting diode LED3 included in the display device DD according to an embodiment.

Referring to FIG. 8A, a side surface SJS1_SF of a first emission structure SJS1 may be inclined. The side surface SJS1_SF of the first emission structure SJS1 may not be parallel to the thickness direction DR3. The side surface SJS1_SF of the first emission structure SJS1 may not be perpendicular to a top surface LE1_UF of a first lower conductive pattern LE1. The first emission structure SJS1 may be formed through a dry etching process, and include the side surface SJS1_SF not parallel to the thickness direction DR3. The first emission structure SJS1 may have a width that gradually decreases from a lower side toward an upper side. In a cross-sectional view, the first emission structure SJS1 may substantially have a tapered shape.

A side surface UE1_SF of a first upper conductive pattern UE1 may be substantially parallel to the thickness direction DR3. Being substantially parallel may include not only a case of being parallel without a margin of error, but also a case of having a difference in a margin of a process error.

A first insulating layer SI1-1 may be in contact (or in direct contact) the side surface SJS1_SF of the first emission structure SJS1 and the side surface UE1_SF of the first upper conductive pattern UE1. An extension direction of a portion, which is in contact (or in direct contact) the side surface SJS1_SF of the first emission structure SJS1, of the first insulating layer SI1-1 may be inclined with respect to the thickness direction DR3. An extension direction of a portion, which is in contact (or in direct contact) the side surface UE1_SF of the first upper conductive pattern UE1, of the first insulating layer SI1-1 may be substantially parallel to the thickness direction DR3. The first insulating layer SI1-1 may be further disposed on a portion of a top surface UE1_UF of the first upper conductive pattern UE1. The first insulating layer SI1-1 may be further disposed on an area of the top surface LE1_UF of the first lower conductive pattern LE1, in which the first emission structure SJS1 is not disposed. A (1-1)-th sub-opening portion S11_OH which exposes a connection area AA1 of the top surface UE1_UF of the first upper conductive pattern UE1 may be defined in the first insulating layer SI1-1.

A first additional insulating layer SI2-1 may be spaced apart from the side surface SJS1_SF of the first emission structure SJS1, the side surface UE1_SF of the first upper conductive pattern UE1, and the top surface UE1_UF of the first upper conductive pattern UE1, with the first insulating layer SI1-1 therebetween. The first additional insulating layer SI2-1 may be disposed on a side surface LE1_SF of the first lower conductive pattern LE1, the side surface SJS1_SF of the first emission structure SJS1, the side surface UE1_SF of the first upper conductive pattern UE1, and the top surface UE1_UF of the first upper conductive pattern UE1. The first additional insulating layer SI2-1 may be further disposed on the top surface LE1_UF of the first lower conductive pattern LE1. On the side surface SJS1_SF of the first emission structure SJS1, an extension direction of the first additional insulating layer SI2-1 may be inclined with respect to the third direction DR3. A (2-1)-th sub-opening portion S21_OH which exposes the connection area AA1 of the top surface UE1_UF of the first upper conductive pattern UE1 may be defined in the first additional insulating layer SI2-1.

A first side reflective layer SRL1 may be spaced apart from the first emission structure SJS1 with the first insulating layer SI1-1 and the first additional insulating layer SI2-1 therebetween. The first side reflective layer SRL1 may be disposed on the side surface LE1_SF of the first lower conductive pattern LE1, the side surface SJS1_SF of the first emission structure SJS1, the side surface UE1_SF of the first upper conductive pattern UE1, and the top surface UE1_UF of the first upper conductive pattern UE1. On the side surface SJS1_SF of the first emission structure SJS1, an extension direction of the first side reflective layer SRL1 may be inclined with respect to the third direction DR3. A (3-1)-th sub-opening portion R1_OH which exposes the connection area AA1 of the top surface UE1_UF of the first upper conductive pattern UE1 may be defined in the first side reflective layer SRL1.

The (1-1)-th sub-opening portion S11_OH of the first insulating layer SI1-1, the (2-1)-th sub-opening portion S21_OH of the first additional insulating layer SI2-1, and the (3-1)-th sub-opening portion R1_OH of the first side reflective layer SRL1 may constitute a first opening portion COP1. An inner side surface of the first insulating layer SI1-1 which defines the (1-1)-th sub-opening portion S11_OH, an inner side surface of the first additional insulating layer SI2-1 which defines the (2-1)-th sub-opening portion S21_OH, and an inner side surface of the first side reflective layer SRL1 which defines the (3-1)-th sub-opening portion R1_OH, may be aligned with each other. A (1-1)-th connection line CL1-1 may be in contact (or in direct contact) the connection area AA1 of the top surface UE1_UF of the first upper conductive pattern UE1 through the first opening portion COP1.

A first planarization layer INS1 may be disposed on the side surface LE1_SF of the first lower conductive pattern LE1 and the side surface SJS1_SF of the first emission structure SJS1. The first planarization layer INS1 may have a portion arranged to correspond to the side surface UE1_SF of the first upper conductive pattern UE1, and another portion disposed on the first upper conductive pattern UE1 and overlapping the first side reflective layer SRL1.

Referring to FIG. 8B, a side surface SJS2_SF of a second emission structure SJS2 may be inclined. The side surface SJS2_SF of the second emission structure SJS2 may not be parallel to the thickness direction DR3. The side surface SJS2_SF of the second emission structure SJS2 may not be perpendicular to a top surface LE2_UF of a second lower conductive pattern LE2. The second emission structure SJS2 may be formed through a dry etching process, and include the side surface SJS2_SF not parallel to the thickness direction DR3. The second emission structure SJS2 may have a width that gradually decreases from a lower side toward an upper side. In a cross-sectional view, the second emission structure SJS2 may substantially have a tapered shape.

A side surface UE2_SF of a second upper conductive pattern UE2 may be substantially parallel to the thickness direction DR3. Being substantially parallel may include not only a case of being parallel without a margin of error, but also a case of having a difference in a margin of a process error.

A second insulating layer SI1-2 may be in contact (or in direct contact) the side surface SJS2_SF of the second emission structure SJS2 and the side surface UE2_SF of the second upper conductive pattern UE2. An extension direction of a portion, which is in contact (or in direct contact) the side surface SJS2_SF of the second emission structure SJS2, of the second insulating layer SI1-2 may be inclined with respect to the thickness direction DR3. An extension direction of a portion, which is in contact (or in direct contact) the side surface UE2_SF of the second upper conductive pattern UE2, of the second insulating layer SI1-2 may be substantially parallel to the thickness direction DR3. The second insulating layer SI1-2 may be further disposed on a portion of a top surface UE2_UF of the second upper conductive pattern UE2. The second insulating layer SI1-2 may be further disposed on an area of the top surface LE2_UF of the second lower conductive pattern LE2, in which the second emission structure SJS2 is not disposed. A (1-2)-th sub-opening portion S12_OH which exposes a connection area AA2 of the top surface UE2_UF of the second upper conductive pattern UE2 may be defined in the second insulating layer SI1-2.

A second additional insulating layer SI2-2 may be spaced apart from the side surface SJS2_SF of the second emission structure SJS2, the side surface UE2_SF of the second upper conductive pattern UE2, and the top surface UE2_UF of the second upper conductive pattern UE2, with the second insulating layer SI1-2 therebetween. The second additional insulating layer SI2-2 may be disposed on a side surface LE2_SF of the second lower conductive pattern LE2, the side surface SJS2_SF of the second emission structure SJS2, the side surface UE2_SF of the second upper conductive pattern UE2, and the top surface UE2_UF of the second upper conductive pattern UE2. The second additional insulating layer SI2-2 may be further disposed on the top surface LE2_UF of the second lower conductive pattern LE2. On the side surface SJS2_SF of the second emission structure SJS2, an extension direction of the second additional insulating layer SI2-2 may be inclined with respect to the third direction DR3. A (2-2)-th sub-opening portion S22_OH which exposes the connection area AA2 of the top surface UE2_UF of the second upper conductive pattern UE2 may be defined in the second additional insulating layer SI2-2.

A second side reflective layer SRL2 may be spaced apart from the second emission structure SJS2 with the second insulating layer SI1-2 and the second additional insulating layer SI2-2 therebetween. The second side reflective layer SRL2 may be disposed on the side surface LE2_SF of the second lower conductive pattern LE2, the side surface SJS2_SF of the second emission structure SJS2, the side surface UE2_SF of the second upper conductive pattern UE2, and the top surface UE2_UF of the second upper conductive pattern UE2. On the side surface SJS2_SF of the second emission structure SJS2, an extension direction of the second side reflective layer SRL2 may be inclined with respect to the third direction DR3. A (3-2)-th sub-opening portion R2_OH which exposes the connection area AA2 of the top surface UE2_UF of the second upper conductive pattern UE2 may be defined in the second side reflective layer SRL2.

The (1-2)-th sub-opening portion S12_OH of the second insulating layer SI1-2, the (2-2)-th sub-opening portion S22_OH of the second additional insulating layer SI2-2, and the (3-2)-th sub-opening portion R2_OH of the second side reflective layer SRL2 may constitute a second opening portion COP2. An inner side surface of the second insulating layer SI1-2 which defines the (1-2)-th sub-opening portion S12_OH, an inner side surface of the second additional insulating layer SI2-2 which defines the (2-2)-th sub-opening portion S22_OH, and an inner side surface of the second side reflective layer SRL2 which defines the (3-2)-th sub-opening portion R2_OH, may be aligned with each other. A (2-2)-th connection line CL2-2 may be in contact (or in direct contact) the connection area AA2 of the top surface UE2_UF of the second upper conductive pattern UE2 through the second opening portion COP2.

A second planarization layer INS2 may be disposed on the side surface LE2_SF of the second lower conductive pattern LE2 and the side surface SJS2_SF of the second emission structure SJS2. The second planarization layer INS2 may have a portion arranged to correspond to the side surface UE2_SF of the second upper conductive pattern UE2, and another portion disposed on the second upper conductive pattern UE2 and overlapping the second side reflective layer SRL2.

Referring to FIG. 8C, a side surface SJS3_SF of a third emission structure SJS3 may be inclined. The side surface SJS3_SF of the third emission structure SJS3 may not be parallel to the thickness direction DR3. The side surface SJS3_SF of the third emission structure SJS3 may not be perpendicular to a top surface LE3_UF of a third lower conductive pattern LE3. The third emission structure SJS3 may be formed through a dry etching process, and include the side surface SJS3_SF not parallel to the thickness direction DR3. The third emission structure SJS3 may have a width that gradually decreases from a lower side toward an upper side. In a cross-sectional view, the third emission structure SJS3 may substantially have a tapered shape.

A side surface UE3_SF of a third upper conductive pattern UE3 may be substantially parallel to the thickness direction DR3. Being substantially parallel may include not only a case of being parallel without a margin of error, but also a case of having a difference in a margin of a process error.

A third insulating layer SI1-3 may be in contact (or in direct contact) the side surface SJS3_SF of the third emission structure SJS3 and the side surface UE3_SF of the third upper conductive pattern UE3. An extension direction of a portion, which is in contact (or in direct contact) the side surface SJS3_SF of the third emission structure SJS3, of the third insulating layer SI1-3 may be inclined with respect to the thickness direction DR3. An extension direction of a portion, which is in contact (or in direct contact) the side surface UE3_SF of the third upper conductive pattern UE3, of the third insulating layer SI1-3 may be substantially parallel to the thickness direction DR3. The third insulating layer SI1-3 may be further disposed on a portion of a top surface UE3_UF of the third upper conductive pattern UE3. The third insulating layer SI1-3 may be further disposed on an area of top surface LE3_UF of the third lower conductive pattern LE3, in which the third emission structure SJS3 is not disposed. A (1-3)-th sub-opening portion S13_OH which exposes a connection area AA3 of the top surface UE3_UF of the third upper conductive pattern UE3 may be defined in the third insulating layer SI1-3.

A third additional insulating layer SI2-3 may be spaced apart from the side surface SJS3_SF of the third emission structure SJS3, the side surface UE3_SF of the third upper conductive pattern UE3, and the top surface UE3_UF of the third upper conductive pattern UE3, with the third insulating layer SI1-3 therebetween. The third additional insulating layer SI2-3 may be disposed on a side surface LE3_SF of the third lower conductive pattern LE3, the side surface SJS3_SF of the third emission structure SJS3, the side surface UE3_SF of the third upper conductive pattern UE3, and the top surface UE3_UF of the third upper conductive pattern UE3. The third additional insulating layer SI2-3 may be further disposed on the top surface LE3_UF of the third lower conductive pattern LE3. On the side surface SJS3_SF of the third emission structure SJS3, an extension direction of the third additional insulating layer SI2-3 may be inclined with respect to the third direction DR3. A (2-3)-th sub-opening portion S23_OH which exposes the connection area AA3 of the top surface UE3_UF of the third upper conductive pattern UE3 may be defined in the third additional insulating layer SI2-3.

A third side reflective layer SRL3 may be spaced apart from the third emission structure SJS3 with the third insulating layer SI1-3 and the third additional insulating layer SI2-3 therebetween. The third side reflective layer SRL3 may be disposed on the side surface LE3_SF of the third lower conductive pattern LE3, the side surface SJS3_SF of the third emission structure SJS3, the side surface UE3_SF of the third upper conductive pattern UE3, and the top surface UE3_UF of the third upper conductive pattern UE3. On the side surface SJS3_SF of the third emission structure SJS3, an extension direction of the third side reflective layer SRL3 may be inclined with respect to the third direction DR3. A (3-3)-th sub-opening portion R3_OH which exposes the connection area AA3 of the top surface UE3_UF of the third upper conductive pattern UE3 may be defined in the third side reflective layer SRL3.

The (1-3)-th sub-opening portion S13_OH of the third insulating layer SI1-3, the (2-3)-th sub-opening portion S23_OH of the third additional insulating layer SI2-3, and the (3-3)-th sub-opening portion R3_OH of the third side reflective layer SRL3 may constitute a third opening portion COP3. An inner side surface of the third insulating layer SI1-3 which defines the (1-3)-th sub-opening portion S13_OH, an inner side surface of the third additional insulating layer SI2-3 which defines the (2-3)-th sub-opening portion S23_OH, and an inner side surface of the third side reflective layer SRL3 which defines the (3-3)-th sub-opening portion R3_OH, may be aligned with each other. The second common electrode CME2 may be in contact (or in direct contact) the connection area AA3 of the top surface UE3_UF of the third upper conductive pattern UE3 through the third opening portion COP3.

A third planarization layer INS3 may be disposed on the side surface LE3_SF of the third lower conductive pattern LE3 and the side surface SJS3_SF of the third emission structure SJS3. The third planarization layer INS3 may have on portion arranged to correspond to the side surface UE3_SF of the third upper conductive pattern UE3, and another portion disposed on the third upper conductive pattern UE3 and overlapping the third side reflective layer SRL3.

Referring to FIGS. 8A to 8C together, with regard to the first insulating layer SI1-1 which covers the side surface SJS1_SF of the first emission structure SJS1, the second insulating layer SI1-2 which covers the side surface SJS2_SF of the second emission structure SJS2, and the third insulating layer SI1-3 which covers the side surface SJS3_SF of the third emission structure SJS3, at least one of the first insulating layer SI1-1, the second insulating layer SI1-2, or the third insulating layer SI1-3 may include a different material from the remaining insulating layers.

The first insulating layer SI1-1 may include a different material from the second insulating layer SI1-2. The first light emitting diode LED1 including the first insulating layer SI1-1 may emit light having a different wavelength from the second light emitting diode LED2 including the second insulating layer SI1-2, and the first insulating layer SI1-1 and the second insulating layer SI1-2 may include different materials.

The first insulating layer SI1-1 may include a different material from the third insulating layer SI1-3. The first light emitting diode LED1 including the first insulating layer SI1-1 may emit light having a different wavelength from the third light emitting diode LED3 including the third insulating layer SI1-3, and the first insulating layer SI1-1 and the third insulating layer SI1-3 may include different materials.

The second insulating layer SI1-2 and the third insulating layer SI1-3 may include the same material. The first light emitting diode LED1 may emit light having a first wavelength, the second light emitting diode LED2 may emit light having a second wavelength, and the third light emitting diode LED3 may emit light having a third wavelength. The first wavelength may be shorter than each of the second wavelength and the third wavelength. The first insulating layer SI1-1 included in the first light emitting diode LED1 which emits light a shorter wavelength may include a different material from the insulating layers of other light emitting diodes. The second insulating layer SI1-2 and the third insulating layer SI1-3 respectively included in the second light emitting diode LED2 and the third light emitting diode LED3, each of which emits light having a relatively long wavelength, may include the same material. However, the second insulating layer SI1-2 and the third insulating layer SI1-3 are not limited thereto, and may include different materials.

The first insulating layer SI1-1 may include a first insulating material, and the second insulating layer SI1-2 may include a second insulating material different from the first insulating material. The first insulating material may include a high-k dielectric (high-k) material compared to the second insulating material. For example, the first insulating material may include at least one of hafnium oxide, lanthanum oxide, zirconium oxide, tantalum oxide, hafnium oxynitride, zirconium oxynitride, tantalum oxynitride, hafnium nitride, lanthanum nitride, or zirconium nitride. The first insulating material may include a material having a dielectric constant (K) of 10 or more. As the first insulating layer SI1-1 includes the high-k material, external quantum efficiency (EQE) of the first light emitting diode LED1 may be improved compared to in case that the first insulating layer SI1-1 includes a material such as silicon oxide and aluminum oxide, having a relatively low dielectric constant.

The second insulating material may include a material having a high band gap energy (E_{g}). For example, the second insulating material may include at least one of silicon oxide or aluminum oxide. The second insulating material may include a material having a band gap energy (E_{g}) of about 6 eV or more. As the second insulating layer SI1-2 includes the material having the high band gap energy, external quantum efficiency of the second light emitting diode LED2 may be improved compared to in case that the second insulating layer SI1-2 may include a material such as hafnium oxide and zirconium oxide.

The third insulating layer SI1-3 may include a third insulating material from the first insulating material. The third insulating material may include a material having a high band gap energy (E_{g}). For example, the third insulating material may include at least one of silicon oxide or aluminum oxide. The third insulating material may include a material having a band gap energy (E_{g}) of about 6 eV or more. As the third insulating layer SI1-3 includes the material having the high band gap energy, external quantum efficiency of the third light emitting diode LED3 may be improved compared to in case that the third insulating layer SI1-3 includes a material such as hafnium oxide and zirconium oxide. The third insulating material may include the same material as the second insulating material. In another embodiment, the third insulating material may include a different material from the second insulating material.

The display device DD according to an embodiment may include multiple light emitting diodes LED1, LED2, and LED3 which emit light having different wavelengths, and at least one of the insulating layers SI1-1, SI1-2, and SI1-3, which cover the side surfaces of the emission structures SJS1, SJS2, and SJS3 included in multiple light emitting diodes LED1, LED2, and LED3, may include a different material from the other insulating layers. For example, the first insulating layer SI1-1 included in the first light emitting diode LED1 which emits light a shorter wavelength may include a different material from the insulating layers of other light emitting diodes. In the display device DD according to an embodiment, the insulating layers may be provided to have different materials so as to be suitable for respective emission wavelengths of the light emitting diodes LED1, LED2, and LED3, thereby improving the external quantum efficiency of each of the light emitting diodes LED1, LED2, and LED3. Accordingly, display efficiency of the display device DD including the light emitting diodes LED1, LED2, and LED3 may be improved.

The first additional insulating layer SI2-1 may include the same material as the first insulating layer SI1-1. The second additional insulating layer SI2-2 may include the same material as the second insulating layer SI1-2. The third additional insulating layer SI2-3 may include the same material as the third insulating layer SI1-3. For example, the first additional insulating layer SI2-1 may include the first insulating material including the high-k material, and the second additional insulating layer SI2-2 and the third additional insulating layer SI2-3 may respectively include the second insulating material and the third insulating material each having the high band gap energy. The material included in the first additional insulating layer SI2-1 may be different from the material included in each of the second additional insulating layer SI2-2 and the third additional insulating layer SI2-3. However, the first additional insulating layer SI2-1, the second additional insulating layer SI2-2, and the third additional insulating layer SI2-3 are not limited thereto, and may include the same material. For example, each of the first additional insulating layer SI2-1, the second additional insulating layer SI2-2, and the third additional insulating layer SI2-3 may include at least one of silicon oxide or aluminum oxide.

Each of the first side reflective layer SRL1, the second side reflective layer SRL2, and the third side reflective layer SRL3 may include a reflective metal. The first side reflective layer SRL1, the second side reflective layer SRL2, and the third side reflective layer SRL3 may include the same material. For example, each of the first side reflective layer SRL1, the second side reflective layer SRL2, and the third side reflective layer SRL3 may include gold, copper, silver, titanium, or aluminum.

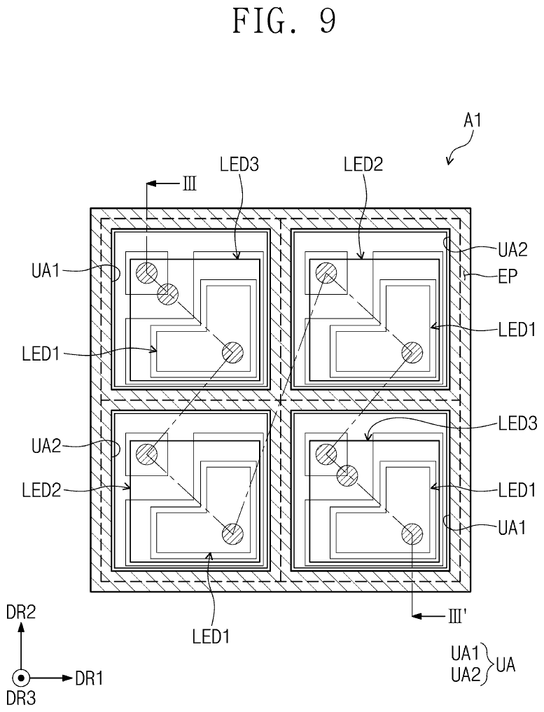

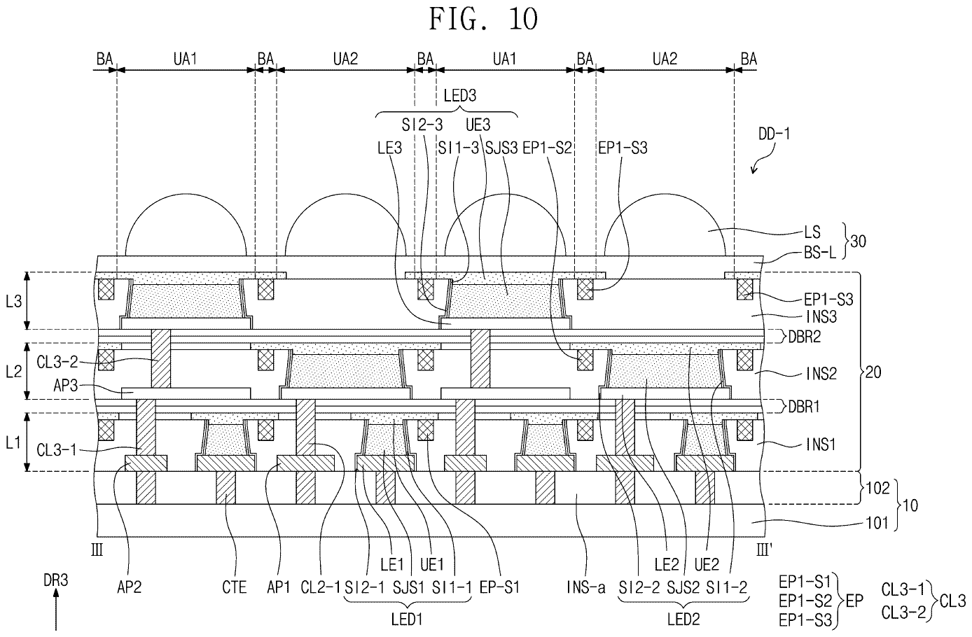

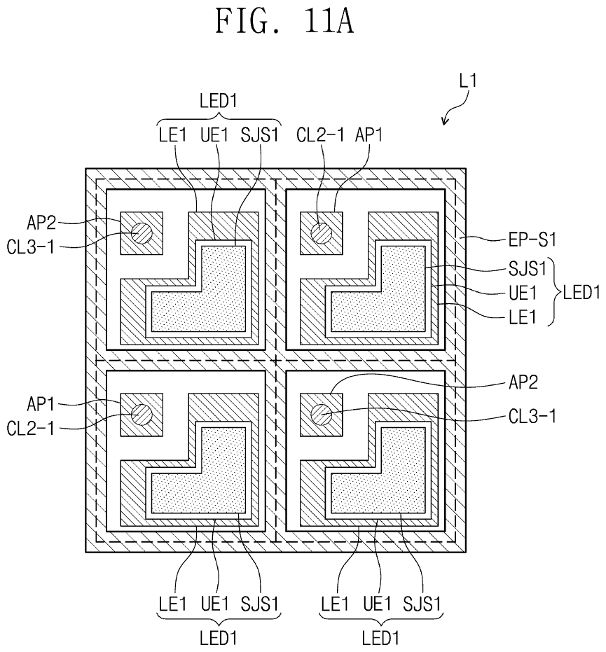

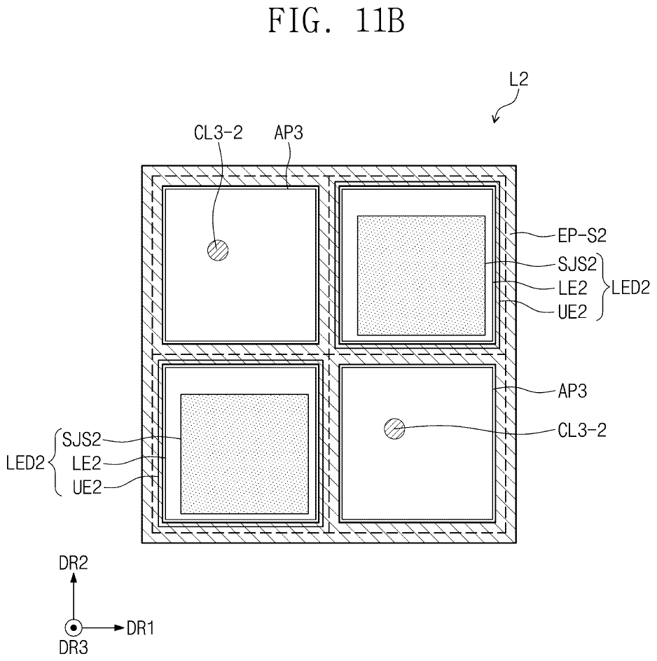

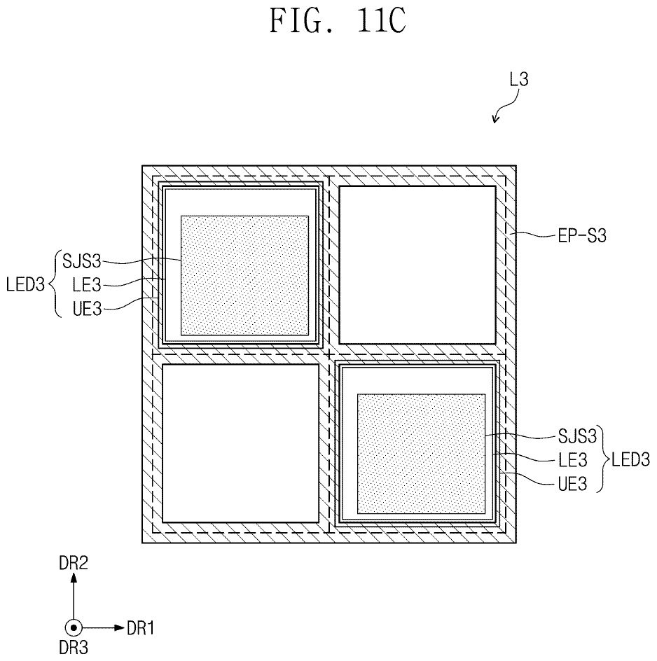

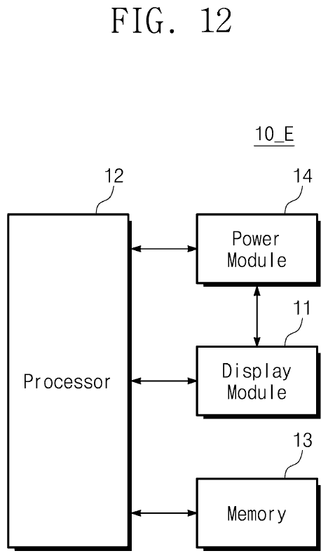

FIG. 9 is an enlarged schematic plan view of a portion of a display device according to an embodiment of the disclosure. FIG. 10 is an enlarged schematic cross-sectional view of a portion of a display device according to an embodiment of the disclosure. FIGS. 11A to 11C are each a schematic plan view of some components of a display device according to an embodiment of the disclosure. FIG. 9 is an enlarged schematic plan view illustrating the partial area A1 of the first area DA illustrated in FIG. 3A. FIG. 10 is a schematic cross-sectional view corresponding to cutting line III-III′ illustrated in FIG. 9. FIGS. 11A to 11C are schematic plan views respectively illustrating planar arrangements of components arranged to correspond to the first layer L1, the second layer L2, and the third layer L3 among the components illustrated in FIG. 9. Meanwhile, FIGS. 9 to 11C illustrate schematic plan views and schematic cross-sectional views each corresponding to a portion of a first areas DA in a display device DD-1 according to another embodiment different from the display device DD according to an embodiment illustrated in FIGS. 5 to 7C.

Referring to FIG. 9, the first area DA may include multiple unit areas UA and a boundary area BA between the unit areas UA. The boundary area BA may be an area overlapped by the electrode pattern EP described above.

Multiple light emitting diodes LED1, LED2, and LED3 are disposed in each of the unit areas UA. The unit areas UA may include a first unit area UA1 overlapped by a first light emitting diode LED1 and a third light emitting diode LED3, and a second unit area UA2 overlapped by the first light emitting diode LED1 and a second light emitting diode LED2. The first light emitting diode LED1, the second light emitting diode LED2, and the third light emitting diode LED3 may be disposed at different layers, and two or more light emitting diodes may be arranged to correspond to each of the unit areas UA. The first unit area UA1 and the second unit area UA2 may be alternately disposed along each of the first direction DR1 and the second direction DR2.

Referring to FIGS. 9 to 11C together, the display device DD-1 may according to an embodiment may include a CMOS wafer 10, an emission structure layer 20, and a lens layer 30.

The CMOS wafer 10 may include a silicon substrate 101. The silicon substrate 101 may include source/drain regions and a gate, which define a transistor. Shallow trench isolation (STI) regions which isolate the transistor and prevent leakage current may be defined in the silicon substrate 101.

The CMOS wafer 10 may further include a contact layer 102 disposed on the silicon substrate 101. In the first area DA, the contact layer 102 may include multiple contact electrodes CTE. The contact electrodes CTE may be electrically connected to the source/drain regions of the silicon substrate 101. The contact electrodes CTE may be formed through a damascene process. The contact electrodes CTE may include metals such as copper or tungsten. The contact electrodes CTE may include a tungsten structure, a titanium layer which surrounds a side surface and a bottom surface of the tungsten structure, and a titanium nitride layer which surrounds the titanium layer. In another embodiment, the contact electrodes CTE may include a copper structure, a tantalum layer which surrounds a side surface and a bottom surface of the copper structure, and a tantalum nitride layer which surrounds the tantalum layer.

The contact layer 102 may include a lower insulating layer INS-a disposed on the silicon substrate 101. The lower insulating layer INS-a may include an oxide layer such as a silicon oxide layer, a silicon nitride layer, a silicon oxynitride layer, or an aluminum oxide layer. Although the lower insulating layer INS-a that is a single layer is illustrated, the lower insulating layer INS-a may be provided in multiple layers. Respective top surfaces of the contact electrodes CTE may define the same plane (or flat surface) together with of a top surface of the lower insulating layer INS-a.

The emission structure layer 20 may be disposed on the CMOS wafer 10, and include multiple layers L1, L2, and L3. In the first area DA, multiple layers L1, L2, and L3 may include multiple light emitting diodes LED1, LED2, and LED3, respectively. However, unlike the embodiment illustrated in FIG. 10, the stacking sequence of a first layer L1 including first light emitting diodes LED1, a second layer L2 including the second light emitting diodes LED2, and a third layer L3 including the third light emitting diodes LED3 may be changed.

The first layer L1 may be disposed on the contact layer 102 of the CMOS wafer 10, and include multiple first light emitting diodes LED1. Multiple first light emitting diodes LED1 may be arranged to correspond to each of the first unit area UA1 and the second unit area UA2.

Each of the first light emitting diodes LED1 may include a first emission structure SJS1 and a first insulating layer SI1-1 disposed on a side surface of the first emission structure SJS1. Each of the first light emitting diodes LED1 may further include a first lower conductive pattern LE1 disposed below the first emission structure SJS1, and a first upper conductive pattern UE1 disposed above the first emission structure SJS1. Each of the first light emitting diodes LED1 may further include a first additional insulating layer SI2-1 disposed outside the first insulating layer SI1-1.

The first lower conductive pattern LE1 may be disposed (or directly disposed) on the contact layer 102. The first lower conductive pattern LE1 may be in contact (or in direct contact) each of the contact electrodes CTE of the contact layer 102. The first lower conductive pattern LE1 may include at least a metal. The first lower conductive pattern LE1 may include a metal layer. The metal layer of the first lower conductive pattern LE1 may be provided to connect the contact electrode CTE of the CMOS wafer 10 to the first lower conductive pattern LE1. The first lower conductive pattern LE1 may further include a transparent conductive oxide layer.

The first emission structure SJS1 may be disposed on the first lower conductive pattern LE1 and include at least an active layer. The first emission structure SJS1 may have a planar area smaller than or the same as that of the first lower conductive pattern LE1 disposed below the first emission structure SJS1. The first emission structure SJS1 may overlap (or entirely overlap) the first lower conductive pattern LE1. As illustrated in FIG. 10, the side surface of the first emission structure SJS1 may be inclined on the basis of the thickness direction DR3. The side surface of the first emission structure SJS1 may not be perpendicular to a top surface of the first lower conductive pattern LE1 of the first emission structure SJS1. For example, the length of the top surface of the first emission structure SJS1 may be smaller the length of the bottom surface of the first emission structure SJS1. The first emission structure SJS1 may be formed through a dry etching process, and include a side surface not parallel to the thickness direction DR3.

The first upper conductive pattern UE1 may be disposed on the first emission structure SJS1 and include a transparent conductive oxide. The first upper conductive pattern UE1 may overlap (or entirely overlap) the first emission structure SJS1. The first upper conductive pattern UE1 may have a planar area smaller than or the same as that of the first emission structure SJS1.

The first insulating layer SI1-1 may cover (or entirely cover) the side surface of the first emission structure SJS1. The first insulating layer SI1-1 may cover the side surface of the first emission structure SJS1 to prevent an etching surface from reducing efficiency during an etching process for forming the first emission structure SJS1. The first insulating layer SI1-1 may cover at least the side surface of the first emission structure SJS1, and cover at least a portion of the first upper conductive pattern UE1 and the first lower conductive pattern LE1.

The first light emitting diode LED1 may further include the first additional insulating layer SI2-1 disposed outside the first insulating layer SI1-1. The first additional insulating layer SI2-1 may cover (or entirely cover) a side surface of the first insulating layer SI1-1. The first additional insulating layer SI2-1 may be provided as multiple layers that are two or more. The first additional insulating layer SI2-1 may cover at least the side surface of the first emission structure SJS1, and cover at least a portion of the first upper conductive pattern UE1 and the first lower conductive pattern LE1. Although not illustrated, the first light emitting diode LED1 may further include the first side reflective layer SRL1 (see FIG. 8A) disposed outside the first additional insulating layer SI2-1.

The first layer L1 may further include first-layer additional conductive patterns AP1 and AP2. The first-layer additional conductive patterns AP1 and AP2 may be respectively in contact (or in direct contact) the contact electrodes CTE of the contact layer 102, and be provided to electrically connect the second light emitting diodes LED2 and the third light emitting diodes LED3, disposed above the first-layer additional conductive patterns AP1 and AP2, to the CMOS wafer 10. The first-layer additional conductive patterns AP1 and AP2 may be disposed at the same layer as the first lower conductive pattern LE1. The first-layer additional conductive patterns AP1 and AP2 may be formed through the same process as the first lower conductive pattern LE1, and include the same stacked structure and the same material as the first lower conductive pattern LE1. The first-layer additional conductive patterns AP1 and AP2 may include a first additional conductive pattern AP1 overlapping each of the second light emitting diodes LED2, and a second additional conductive pattern AP2 overlapping each of the third light emitting diodes LED3.

The first layer L1 may further include a first planarization layer INS1 disposed between at least the first light emitting diodes LED1. The first planarization layer INS1 may overlap the unit areas UA and the boundary area BA, and fill an area in which the first light emitting diodes LED1 are not disposed. The first planarization layer INS1 may include an organic material. A top surface of the first planarization layer INS1 may define the same plane (or flat surface) together with a top surface of the first upper conductive pattern UE1 of the first light emitting diodes LED1.

The second layer L2 may be disposed on the first layer L1, and may include multiple second light emitting diodes LED2. Multiple second light emitting diodes LED2 may be arranged to correspond to the second unit area UA2. On a unit area, the number of the arranged first light emitting diodes LED1 may be twice the number of the arranged second light emitting diodes LED2. As illustrated in FIG. 10, in case that an area including two first unit areas UA1 and two second unit areas UA2 is defined as a unit surface area, four first light emitting diodes LED1 and two second light emitting diodes LED2 may be disposed in the unit surface area.

Each of the second light emitting diodes LED2 may include a second emission structure SJS2 and a second insulating layer SI1-2 disposed on a side surface of the second emission structure SJS2. Each of the second light emitting diodes LED2 may further include a second lower conductive pattern LE2 disposed below the second emission structure SJS2, and a second upper conductive pattern UE2 disposed above the second emission structure SJS2. Each of the second light emitting diodes LED2 may further include a second additional insulating layer SI2-2 disposed outside the second insulating layer SI1-2.

The second lower conductive pattern LE2 may include a transparent conductive oxide. The second lower conductive pattern LE2 may not include a metal. Unlike the first lower conductive pattern LE1, the second lower conductive pattern LE2 may not include the metal but include only the transparent conductive oxide. The second lower conductive pattern LE2 may include only the transparent conductive oxide in order not to block light generated from the first light emitting diode LED1 disposed below the second lower conductive pattern LE2.

The second emission structure SJS2 may be disposed on the second lower conductive pattern LE2 and include at least an active layer. The second emission structure SJS2 may have a planar area smaller than or the same as that of the second lower conductive pattern LE2 disposed below the second emission structure SJS2. The second emission structure SJS2 may overlap (or entirely overlap) the second lower conductive pattern LE2. As illustrated in FIG. 10, the side surface of the second emission structure SJS2 may be inclined on the basis of the thickness direction DR3. The side surface of the second emission structure SJS2 may not be perpendicular to a top surface of the second lower conductive pattern LE2 of the second emission structure SJS2. For example, the length of the top surface of the second emission structure SJS2 may be smaller the length of the bottom surface of the second emission structure SJS2. The second emission structure SJS2 may be formed through a dry etching process, and include a side surface not parallel to the thickness direction DR3.

The second upper conductive pattern UE2 may be disposed on the second emission structure SJS2 and include a transparent conductive oxide. The second upper conductive pattern UE2 may overlap (or entirely overlap) the second emission structure SJS2. The second upper conductive pattern UE2 may have a planar area smaller than or the same as that of the second emission structure SJS2.

The second insulating layer SI1-2 may cover (or entirely cover) the side surface of the second emission structure SJS2. The second insulating layer SI1-2 may cover the side surface of the second emission structure SJS2 to prevent an etching surface from reducing the efficiency during an etching process for forming the second emission structure SJS2. The second insulating layer SI1-2 may cover at least the side surface of the second emission structure SJS2, and cover at least a portion of the second upper conductive pattern UE2 and the second lower conductive pattern LE2.

The second light emitting diode LED2 may further include the second additional insulating layer SI2-2 disposed outside the second insulating layer SI1-2. The second additional insulating layer SI2-2 may cover (or entirely cover) a side surface of the second insulating layer SI1-2. The second additional insulating layer SI2-2 may be provided as multiple layers that are two or more. The second additional insulating layer SI2-2 may cover at least the side surface of the second emission structure SJS2, and cover at least a portion of the second upper conductive pattern UE2 and the second lower conductive pattern LE2. Although not illustrated, the second light emitting diodes LED2 may further include the second side reflective layer SRL2 (see FIG. 8B) disposed outside the second additional insulating layer SI2-2.

A planar area of each of multiple second light emitting diodes LED2 may be larger than or the same as a planar area of each of multiple first light emitting diodes LED1. A planar area of each of the second emission structures SJS2 included in the second light emitting diodes LED2 may be larger than or the same as a planar area of each of the first emission structures SJS2 included in the first light emitting diodes LED1.

The second layer L2 may further include a second-layer additional conductive pattern AP3. The second-layer additional conductive pattern AP3 may be provided for an electrical connection between the CMOS wafer 10 and the third light emitting diodes LED3 disposed above the second-layer additional conductive pattern AP3. The second-layer additional conductive pattern AP3 may be disposed at the same layer as the second lower conductive pattern LE2. The second-layer additional conductive pattern AP3 may be formed through the same process as the second lower conductive pattern LE2, and include the same stacked structure and the same material as the second lower conductive pattern LE2. At least a portion of the second-layer additional conductive pattern AP3 may overlap the third light emitting diodes LED3.

The second layer L2 may further include a second planarization layer INS2 disposed between at least the second light emitting diodes LED2. The second planarization layer INS2 may overlap the unit areas UA and the boundary area BA, and fill an area in which the second light emitting diodes LED2 are not disposed. The second planarization layer INS2 may include an organic material. A top surface of the second planarization layer INS2 may define the same plane (or flat surface) together with a top surface of the second upper conductive pattern UE2 of the second light emitting diodes LED2.

The third layer L3 may be disposed on the second layer L2, and may include multiple third light emitting diodes LED3. Multiple third light emitting diodes LED3 may be arranged to correspond to the first unit area UA1. On a unit area, the number of the arranged first light emitting diodes LED1 may be twice the number of the arranged third light emitting diodes LED3. As illustrated in FIG. 10, in case that an area including two first unit areas UA1 and two second unit areas UA2 is defined as a unit surface area, two third light emitting diodes LED3 and four first light emitting diodes LED1 may be disposed in the unit surface area.

Each of the third light emitting diodes LED3 may include a third emission structure SJS3, a third lower conductive pattern LE3 disposed below the third emission structure SJS3, and a third upper conductive pattern UE3 disposed above the third emission structure SJS3.

The third lower conductive pattern LE3 may include a transparent conductive oxide. The third lower conductive pattern LE3 may not include a metal. Unlike the first lower conductive pattern LE1, the third lower conductive pattern LE3 may not include the metal but include only the transparent conductive oxide. The third lower conductive pattern LE3 may include only the transparent conductive oxide in order not to block light generated from the first light emitting diode LED1 and the second light emitting diode LED2, disposed below the third lower conductive pattern LE3.

The third emission structure SJS3 may be disposed on the third lower conductive pattern LE3 and include at least an active layer. The third emission structure SJS3 may have a planar area smaller than or the same as the third lower conductive pattern LE3 disposed below the third emission structure SJS3. The third emission structure SJS3 may overlap (or entirely overlap) the third lower conductive pattern LE3. As illustrated in FIG. 10, a side surface of the third emission structure SJS3 may be inclined on the basis of the thickness direction DR3. The side surface of the third emission structure SJS3 may not be perpendicular to a top surface of the third lower conductive pattern LE3 of the third emission structure SJS3. For example, the length of the top surface of the third emission structure SJS3 may be smaller the length of the bottom surface of the third emission structure SJS3. The third emission structure SJS3 may be formed through a dry etching process, and include a side surface not parallel to the thickness Direction DR3.

The third upper conductive pattern UE3 may be disposed on the third emission structure SJS3 and include a transparent conductive oxide. The third upper conductive pattern UE3 may overlap (or entirely overlap) the third emission structure SJS3. The third upper conductive pattern UE3 may have a planar area smaller than or the same as the third emission structure SJS3.

The third insulating layer SI1-3 may cover (or entirely cover) the side surface of the third emission structure SJS3. The third insulating layer SI1-3 may cover the side surface of the third emission structure SJS3 to prevent an etching surface from reducing the efficiency during an etching process for forming the third emission structure SJS3. The third insulating layer SI1-3 may cover at least the side surface of the third emission structure SJS3, and cover at least a portion of the third upper conductive pattern UE3 and the third lower conductive pattern LE3.

The third light emitting diode LED3 may further include a third additional insulating layer SI2-3 disposed outside the third insulating layer SI1-3. The third additional insulating layer SI2-3 may cover (or entirely cover) a side surface of the third insulating layer SI1-3. The third additional insulating layer SI2-3 may be provided as multiple layers that are two or more. The third additional insulating layer SI2-3 may cover at least the side surface of the third emission structure SJS3, and cover at least a portion of the third upper conductive pattern UE3 and the third lower conductive pattern LE3. Although not illustrated, the third light emitting diodes LED3 may further include the third side reflective layer SRL3 (see FIG. 8C) disposed outside the third additional insulating layer SI2-3.

A planar area of each of multiple third light emitting diodes LED3 may be larger than or the same as a planar area of each of multiple second light emitting diodes LED2. A planar area of each of the third emission structures SJS3 included in the third light emitting diodes LED3 may be larger than or the same as a planar area of each of the second emission structures SJS2 included in the second light emitting diodes LED2.

The third layer L3 may further include a third planarization layer INS3 disposed between at least the third light emitting diodes LED3. The third planarization layer INS3 may overlap the unit areas UA and the boundary area BA, and fill an area in which the third light emitting diodes LED3 are not disposed. The third planarization layer INS3 may include an organic material. A top surface of the third planarization layer INS3 may define the same plane (or flat surface) together with a top surface of the third upper conductive pattern UE3 of the third light emitting diodes LED3.

The emission structure layer 20 may further include an electrode pattern EP, and the electrode pattern EP has a mesh structure in a plan view. The electrode pattern EP may include sub-electrode patterns EP1-S1, EP1-S2, and EP1-S3 arranged to correspond to multiple layers L1, L2, and L3, respectively.

Each of the sub-electrode patterns EP1-S1, EP1-S2, and EP1-S3 may be electrically connected to one corresponding light emitting diode among multiple light emitting diodes LED1, LED2, and LED3. A first sub-electrode pattern EP1-S1 disposed in the first layer L1 may be electrically connected to the first upper conductive pattern UE1 of the first light emitting diode LED1, a second sub-electrode pattern EP1-S2 disposed in the second layer L2 may be electrically connected to the second upper conductive pattern UE2 of the second light emitting diode LED2, and a third sub-electrode pattern EP1-S3 disposed in the third layer L3 may be electrically connected to the third upper conductive pattern UE3 of the third light emitting diode LED3. The first sub-electrode pattern EP1-S1 may be electrically connected to a lower portion of the first upper conductive pattern UE1, the second sub-electrode pattern EP1-S2 may be electrically connected to a lower portion of the second upper conductive pattern UE2, and the third sub-electrode pattern EP1-S3 may be electrically connected to a lower portion of the third upper conductive pattern UE3.

Each of the sub-electrode patterns EP1-S1, EP1-S2, and EP1-S3 may not overlap each of the first emission structure SJS1, the second emission structure SJS2, and the third emission structure SJS3 in a plan view. Each of the sub-electrode patterns EP1-S1, EP1-S2, and EP1-S3 may be arranged to overlap the boundary area BA. In the first area DA, the sub-electrode patterns EP1-S1, EP1-S2, and EP1-S3 may not electrically connect the light emitting diodes LED1, LED2, and LED3 disposed at multiple layers L1, L2, and L3, respectively. The light emitting diodes LED1, LED2, and LED3 disposed at multiple layers L1, L2, and L3, respectively, may be electrically connected to each other by the sub-electrode patterns EP1-S1, EP1-S2, and EP1-S3 disposed in the second area NDA1 (see FIG. 3A).

The emission structure layer 20 may further include optical layers DBR1 and DBR2. The optical layers DBR1 and DBR2 may be disposed in at least one of a space between the first layer L1 and the second layer L2 or a space between the second layer L2 and the third layer L3. The optical layers DBR1 and DBR2 may include, for example, a first optical layer DBR1 disposed between the first layer L1 and the second layer L2, and a second optical layer DBR2 disposed between the second layer L2 and the third layer L3. Any one of the first optical layer DBR1 and the second optical layer DBR2 may be omitted.

The emission structure layer 20 may further include connection lines CL2-1, CL3-1, and CL3-2. Each of the connection lines CL2-1, CL3-1, and CL3-2 may be provided to electrically connect the second light emitting diodes LED2 and the third light emitting diodes LED3 to the CMOS wafer 10. Each of the connection lines CL2-1, CL3-1, and CL3-2 may be formed through the damascene process. Each of the connection lines CL2-1, CL3-1, and CL3-2 may include a metal such as copper or tungsten.

A (2-1)-th connection line CL2-1 may be disposed below each of the second light emitting diodes LED2. The (2-1)-th connection line CL2-1 may overlap the second light emitting diode LED2 in a plan view, and be provided to electrically connect the CMOS wafer 10 to the second light emitting diode LED2. The second lower conductive pattern LE2 of the second light emitting diode LED2 may be electrically connected to the CMOS wafer 10 through the (2-1)-th connection line CL2-1 and the first additional conductive pattern AP1 which are disposed, in sequence, between the second lower conductive pattern LE2 and the CMOS wafer 10.

A third connection line CL3 may be disposed below each of the third light emitting diodes LED3. The third connection line CL3 may overlap the third light emitting diode LED3 in a plan view, and be provided to electrically connect the CMOS wafer 10 to the third light emitting diode LED3. The third connection line CL3 may include a (3-1)-th connection line CL3-1 disposed between the third lower conductive pattern LE3 of the third light emitting diode LED3 and the third additional conductive pattern AP3, and a (3-2)-th connection line CL3-2 disposed between the third additional conductive pattern AP3 and the second additional conductive pattern AP2. The third lower conductive pattern LE3 of the third light emitting diode LED3 may be electrically connected to the CMOS wafer 10 through the (3-1)-th connection line CL3-1, the third additional conductive pattern AP3, the (3-2)-th connection line CL3-2, and the second additional conductive pattern AP2 which are disposed, in sequence, between the third lower conductive pattern LE3 and the CMOS wafer 10.

The first light emitting diodes LED1, the second light emitting diodes LED2, and the third light emitting diodes LED3 may not at least partially overlap each other in a plan view. In a plan view, a portion of each of the first light emitting diodes LED1 may overlap the second light emitting diode LED2, and the remaining portion may not overlap the second light emitting diode LED2. Each of the first light emitting diodes LED1 may not overlap the third light emitting diode LED3 in a plan view. In a plan view, a portion of each of the second light emitting diodes LED2 may overlap each of the first light emitting diode LED1 and the third light emitting diode LED3, and the remaining portion may not overlap each of the first light emitting diode LED1 and the third light emitting diode LED3. In a plan view, a portion of each of the third light emitting diodes LED3 may overlap the second light emitting diode LED2, and the remaining portion may not overlap the second light emitting diode LED2. The first light emitting diodes LED1, the second light emitting diodes LED2, and the third light emitting diodes LED3 may not overlap other light emitting diodes on areas electrically connected to the connection lines CL2-1, CL3-1 and CL3-2, respectively.

The lens layer 30 may be disposed on the emission structure layer 20, and include multiple lenses LS. The lens layer 30 may further include a passivation layer BS-L which provides a base surface on which the lenses LS are disposed. The passivation layer BS-L may be disposed on the third layer L3 and protect the light emitting diodes LED1, LED2, and LED3 disposed below the passivation layer BS-L. The passivation layer BS-L may include an organic material or an inorganic material.

The lenses LS may be arranged to overlap at least the light emitting diodes LED1, LED2, and LED3. As illustrated in FIG. 10, the lenses LS may be arranged to correspond to the first unit area UA1 and the second unit area UA2, respectively. The lenses LS may be provided in one per first unit area UA1, and provided in one per second unit area UA2. The lens LS provided in the first unit area UA1 may be arranged to correspond to one first light emitting diode LED1 and one third light emitting diode LED3, and the lens LS provided in the second unit area UA2 may be arranged to correspond to one first light emitting diode LED1 and one second light emitting diode LED2. Each of the lenses LS may have a circular shape in a plan view, and a diameter of the each of the lenses LS may be 1 micrometer or less.

The display device according to the embodiment has the stacked structure of the light emitting diodes provided in multiple layers, thereby having the high resolution, and the portion of multiple light emitting diodes may include the different insulating layer. In the display device according to the embodiment, the insulating layers may be provided to have the different materials so as to be suitable for the respective emission wavelengths of the light emitting diodes which emit the light having the different wavelengths, thereby improving the external quantum efficiency of the light emitting diodes. Accordingly, the display efficiency of the display device may be improved.

The display device according to the embodiment can be applied to various electronic devices. The electronic device according to one embodiment may include the display device described above, and may further include modules or devices having additional functions in addition to the display device.

FIG. 12 is a schematic block diagram of an electronic device according to one embodiment. Referring to FIG. 12, the electronic device 10_E according to one embodiment may include a display module 11, a processor 12, a memory 13, and a power module 14. The display module 11 may include the display device DD as described in FIGS. 1 to 11C.

The processor 12 may include at least one of a central processing unit (e.g., CPU), an application processor (e.g., AP), a graphic processing unit (e.g., GPU), a communication processor (e.g., CP), an image signal processor (e.g., ISP), and a controller.

The memory 13 may store data information necessary for the operation of the processor 12 or the display module 11. In case that the processor 12 executes an application stored in the memory 15, an image data signal and/or an input control signal is transmitted to the display module 11, and the display module 11 can process the received signal and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10_E described above may be included in the display device according to the embodiments described above. In addition, some of the individual modules functionally included in one module may be included in the display device, and other parts may be provided separately from the display device. For example, the display device may include the display module 11, and the processor 12, the memory 13, and the power module 14 may be provided in the form of other devices in the electronic device 10_E other than the display device.

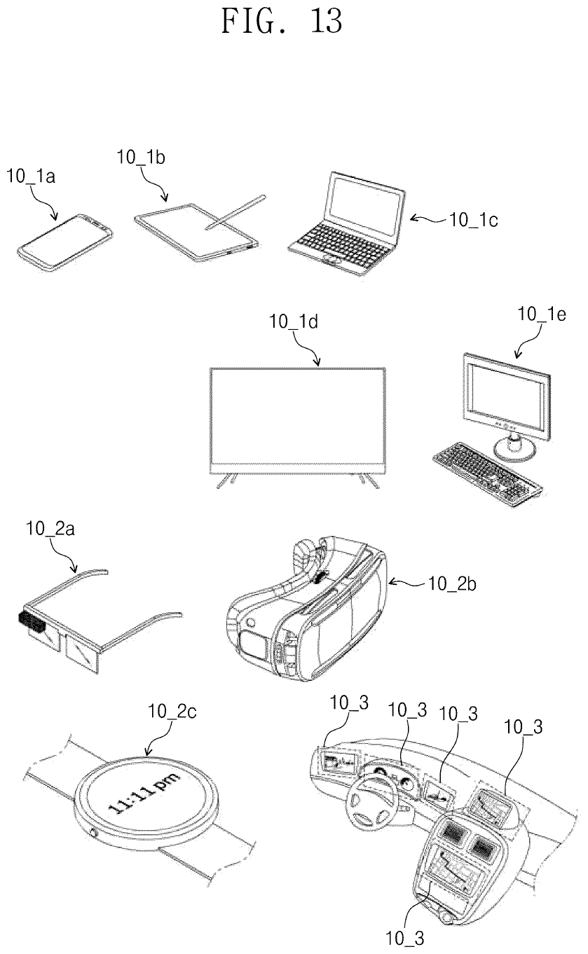

FIG. 13 is a schematic diagram of an electronic device according to various embodiments. Referring to FIG. 13, various electronic devices to which display devices according to embodiments are applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head mounted display 10_2b, and a smart watch 10_2c, and vehicle electronic devices 10_3 including display modules such as a CID (e.g., Center Information Display) and a room mirror display arranged on a dashboard, center fascia, and dashboard of an automobile.

In the above, description has been made with reference to embodiments of the disclosure, but those skilled or of ordinary skill in the art may understand that various modifications and changes may be made to the disclosure insofar as such modifications and changes do not depart from the spirit and technical scope of the disclosure set forth in the claims to be described later. Therefore, the technical scope of the disclosure is not to be limited to the contents stated in the detailed description of the specification, but should be determined by the claims.

What is claimed is:

1. A display device comprising:
a complementary metal oxide semiconductor (CMOS) wafer; and
an emission structure layer disposed on the CMOS wafer,
wherein the emission structure layer comprises:
a plurality of first light emitting diodes which are disposed on the CMOS wafer and emit light having a first wavelength;
a plurality of second light emitting diodes which are disposed on the CMOS wafer and emit light having a second wavelength different from the first wavelength; and
a plurality of third light emitting diodes which are disposed on the CMOS wafer and emit light having a third wavelength different from the first wavelength and the second wavelength,
each of the plurality of first light emitting diodes comprises a first emission structure and a first insulating layer which covers a side surface of the first emission structure,
each of the plurality of second light emitting diodes comprises a second emission structure and a second insulating layer which covers a side surface of the second emission structure,
each of the plurality of third light emitting diodes comprises a third emission structure and a third insulating layer which covers a side surface of the third emission structure, and
at least one of the first insulating layer, the second insulating layer, and the third insulating layer comprises a different material from the remaining insulating layers.

2. The display device of claim 1, wherein the first insulating layer comprises a different material from the second insulating layer, and the second insulating layer and the third insulating layer comprise a same material.

3. The display device of claim 1, wherein the first insulating layer, the second insulating layer, and the third insulating layer comprise different materials.

4. The display device of claim 1, wherein
the first insulating layer is in contact with the side surface of the first emission structure,
the second insulating layer is in contact with the side surface of the second emission structure, and
the third insulating layer is in contact with the side surface of the third emission structure.

5. The display device of claim 1, wherein
each of the plurality of first light emitting diodes further comprises a first additional insulating layer spaced apart from the first emission structure with the first insulating layer disposed between each first light emitting diode and the first additional insulating layer,
each of the plurality of second light emitting diodes further comprises a second additional insulating layer spaced apart from the second emission structure with the second insulating layer disposed between each second light emitting diode and the first additional insulating layer, and
each of the plurality of third light emitting diodes further comprises a third additional insulating layer spaced apart from the third emission structure with the third insulating layer disposed between each third light emitting diode and the third additional insulating layer.

6. The display device of claim 1, wherein at least a portion of each of the plurality of first light emitting diodes does not overlap the plurality of second light emitting diodes and the plurality of third light emitting diodes in a plan view.

7. The display device of claim 1, wherein a first insulating material comprised in the first insulating layer comprises a high-k dielectric material compared to a second insulating material comprised in the second insulating layer.

8. The display device of claim 7, wherein the first insulating material comprises at least one of hafnium oxide, lanthanum oxide, zirconium oxide, tantalum oxide, hafnium oxynitride, zirconium oxynitride, tantalum oxynitride, hafnium nitride, lanthanum nitride, or zirconium nitride.

9. The display device of claim 7, wherein the second insulating material comprises at least one of silicon oxide or aluminum oxide.

10. The display device of claim 1, wherein the first wavelength is shorter than each of and the second wavelength and the third wavelength.

11. The display device of claim 1, wherein
each of the plurality of first light emitting diodes further comprises a first lower conductive pattern disposed below the first emission structure, and a first upper conductive pattern disposed above the first emission structure,
each of the plurality of second light emitting diodes further comprises a second lower conductive pattern disposed below the second emission structure, and a second upper conductive pattern disposed above the second emission structure, and
each of the plurality of third light emitting diodes further comprises a third lower conductive pattern disposed below the third emission structure, and a third upper conductive pattern disposed above the third emission structure.

12. The display device of claim 1, further comprising:
a plurality of lenses disposed on the emission structure layer and overlapping at least some of the plurality of first light emitting diodes, the plurality of second light emitting diodes, and the plurality of third light emitting diodes.

13. The display device of claim 1, wherein the CMOS wafer comprises:
a first area in which the plurality of first light emitting diodes, the plurality of second light emitting diodes, and the plurality of third light emitting diodes are respectively disposed; and
a second area provided outside the first area in a plan view.

14. The display device of claim 1, wherein the emission structure layer further comprises a common electrode electrically connected to at least a portion of the plurality of first light emitting diodes, the plurality of second light emitting diodes, and the plurality of third light emitting diodes.

15. The display device of claim 1, wherein the emission structure layer further comprises a planarization layer disposed between at least some of the plurality of first light emitting diodes, the plurality of second light emitting diodes, and the plurality of third light emitting diodes.

16. An electronic device comprising:
a display module; and
a processor including at least one of a central processing unit, an application processor, a graphic processing unit, a communication processor, an image signal processor, and a controller, wherein
the display module includes:
a complementary metal oxide semiconductor (CMOS) wafer; and
an emission structure layer disposed on the CMOS wafer,
the emission structure layer comprises:
a first layer disposed on the CMOS wafer and comprising a plurality of first light emitting diodes which emit light having a first wavelength; and
a second layer disposed on the first layer and comprising a plurality of second light emitting diodes which emit light having a second wavelength different from the first wavelength,
each of the plurality of first light emitting diodes comprises a first emission structure and a first insulating layer which covers a side surface of the first emission structure,
each of the plurality of second light emitting diodes comprises a second emission structure and a second insulating layer which covers a side surface of the second emission structure, and
the first insulating layer and the second insulating layer comprise different materials.

17. The electronic device of claim 16, wherein
the first insulating layer is in contact with the side surface of the first emission structure, and
the second insulating layer is in contact with the side surface of the second emission structure.

18. The electronic device of claim 16, wherein
the first layer further comprises a first planarization layer between at least the plurality of first light emitting diodes, and
the second layer further comprises a second planarization layer between at least the plurality of second light emitting diodes.

19. The electronic device of claim 16, wherein a first insulating material comprised in the first insulating layer comprises a high-k dielectric material compared to a second insulating material comprised in the second insulating layer.

20. The electronic device of claim 19, wherein
the first insulating material comprises at least one of hafnium oxide, lanthanum oxide, zirconium oxide, tantalum oxide, hafnium oxynitride, zirconium oxynitride, tantalum oxynitride, hafnium nitride, lanthanum nitride, or zirconium nitride, and
the second insulating material comprises at least one of silicon oxide or aluminum oxide.
